(19) United States
(12) Patent Application Publication
(10) Pub. No.: US 2004/0153902 A1
(43) Pub. Date: Aug. 5, 2004

(54) Serial flash integrated circuit having error detection and correction

(75) Inventors: Michael G. Machado, Boulder, CO (US); Chris Van Genderen, San Jose, CA (US); Poongyeub Lee, San Jose, CA (US); Joo Weon Park, Pleasanton, CA (US)

Correspondence Address: ALTERA LAW GROUP, LLC, 6500 CITY WEST PARKWAY, SUITE 100, MINNEAPOLIS, MN, 55344-7704, US

(73) Assignee: NexFlash Technologies, Inc., San Jose, CA

(21) Appl. No.: 10/349,748

(22) Filed: Jan. 21, 2003

(51) Int. Cl. G11C 29/00

(52) U.S. Cl. 714/710

(57) ABSTRACT

A serial flash integrated circuit is provided with an integrated error correction coding (“ECC”) system that is used with an integrated volatile page memory for fast automatic data correction. The ECC code has the capability of correcting any one or two bit errors that might occur on a page of the flash memory array. One bit corrections are done automatically in hardware during reads or transfer to the page memory, while two-bit corrections are handled in external software, firmware or hardware. The ECC system uses a syndrome generator for generating both write and read syndromes, and an error trapper to identify the location of single bit errors using very little additional chip space. The flash memory array may be refreshed from the page memory to correct any detected errors. Data status is made available to the application prior to the data. The use of the ECC is optional.

### BACKGROUND OF THE INVENTION

1. Field of the Invention

The present invention relates to nonvolatile semiconductor memory integrated circuits, and more particularly to a serial flash memory integrated circuits having error detection and correction.

2. Description of the Related Art

A “flash” memory array is a type of nonvolatile semiconductor memory array that retains stored data when power is removed. Many different types of data cells suitable for flash memory are known, including a class of single transistor devices that are based on the storage of charge in discrete trapping centers of a dielectric layer of the structure, and another class of devices that are based on the storage of charge on a conducting or semiconducting layer that is completely surrounded by a dielectric, typically an oxide. Stored charge typically is in the form of electrons, which typically are removed from the charge storage structure using the Fowler-Nordheim mechanism to achieve one state, typically called an erased state, and which typically are injected into the charge storage structure using the Fowler-Nordheim (“FN”) mechanism, the channel hot electron (“CHE”) mechanism, the channel induced secondary electron injection (“CHISEI”) mechanism, or the source side injection (“SSI”) mechanism to achieve another state, typically called a “programmed” state. Techniques are also known for achieving multiple bit storage in a single transistor nonvolatile memory cell by programming the multiple bits into a memory cell as different voltage levels.

Unfortunately, data errors occasionally occur in flash memory. These data errors sometimes occur due to defects arising in the manufacturing process, but they can also occur as the memory is used because of two phenomena inherent to the flash data cell: memory disturb and oxide rupture. Memory disturb and oxide rupture will both cause a data cell in a flash memory array to loose its value. Memory disturb is temporary, and the cell may be used after re-programming. Oxide rupture is a permanent disablement of the data cell.

Memory disturb is a much more serious problem in flash memories used with applications that generally perform random writes than in flash memories used with applications that generally perform sequential writes. Writing data in random order on the flash media causes more stress to the data cells than writing data in sequential order, so that the accumulated stress is greater and memory disturb more frequent in flash memories used with random writing applications. Applications that require file systems typically store general purpose data and typically perform mostly random writes to the flash media. An example of a general purpose data application is the digital set top box. Applications such as digital cameras and audio recording devices typically perform streaming writes, a type of sequential write, to the flash media.

A concept called data refresh commonly is used to combat memory disturb in flash memory applications that demand random writing (more data cell stress). The standard mechanism to refresh a flash device is to estimate or count the number of erase/program operations that have occurred over the flash memory array, and then to refresh the static data within the device after a predetermined number of cycles have occurred. The number of erase/program operations are optimized to the worst case so that all parts will be able to meet specification. This operation will reset the stress on the data cells and prevent disturb errors from occurring. However, data refresh is very demanding on the firmware and system using the flash device, and often cannot be accommodated for in system designs. Examples of the demands made by data refresh include power consumption, use of clock cycles to the detriment of other memory processes, and tying up of system resources. Moreover, data refresh accelerates the wear on each data cell by placing more erase/program cycles on the data cell than may be necessary. This means that under most circumstances, the part will be prematurely worn by refreshing too often, leading to such failure modes as oxide rupture.

Error correction code (“ECC”) systems have been developed to combat data errors in data storage applications. A group of data bits is protected by an ECC system by encoding or mapping them into a different group of bits referred to as an ECC codeword. The specific mapping is determined by the choice of which ECC code is used. The ECC codewords generated by the ECC codes contain more bits than the group of data bits they protect, thereby providing redundancy. When a group of data bits is to be stored in a storage system, it is first mapped into an ECC codeword. It is the ECC codeword that is stored. When retrieval of the data is requested, the ECC codeword is retrieved from storage and decoded. Decoding determines the original group of data bits from an ECC codeword. The extra redundancy in the ECC codeword allows for the detection of errors that occurred during storage. The extra redundancy can also allow for the recovery of the original group of data bits even in the presence of errors. This is referred to as correction. The number of bits that can be detected and corrected depend upon the choice of ECC code, the number of bits or size of the ECC codeword, and the size of the group of data bits it represents.

Although ECC codewords may or may not bear a resemblance to the data they represent, most ECC systems employ an ECC code that generate ECC codewords in which the first part is a copy of the group of data bits it represents. In such systems, the only difference between the ECC codeword and the group of data bits it represents is the extra redundancy bits at the end of the ECC codeword that follow the data bits. These extra redundancy bits are commonly referred to as the ECC bits (or bytes), the check bits (or bytes), the write syndrome, or simply as the syndrome. Employing an ECC code that creates codewords containing a copy of the data bits is useful because less processing is required during encoding and decoding, and the ECC system is easier to understand and debug.

An ECC system for data storage applications typically has a write syndrome generator, storage subsystem, read syndrome generator, and an ECC correction subsystem. Typically, a group of data bits that is to be stored in the storage subsystem is run through the write syndrome generator. The resulting write syndrome is appended to the data bits to form the ECC codeword, which is stored in the storage subsystem. To retrieve the data, the ECC codeword is retrieved from the storage subsystem and run through a read syndrome generator to generate a read syndrome. The ECC system uses the resulting read syndrome to detect if an error has occurred. If it has, the read syndrome can be processed by the ECC correction subsystem to determine which bits in the ECC codeword are incorrect, whereupon the ECC correction subsystem can correct those bits.

One characteristic of the typical ECC system is that the entire ECC codeword must be processed by the read syndrome generator before a read syndrome is available. Because correction is based upon the read syndrome, no-correction can occur until the entire ECC codeword has been processed during data retrieval.

The typical ECC system for data storage applications described above can have simplified implementations, depending on the choice of ECC code and the specific ECC system design. A common simplified implementation is to share circuitry between the write syndrome generator and read syndrome generator. Some implementations share all circuitry and use a single syndrome generator to generate both write and read syndromes.

ECC systems have been used in semiconductor memory devices such as DRAMs, EEPROMs, and flash memory. These ECC systems typically employ a Hamming ECC code. Hamming codes can correct 1 bit in error within the ECC codeword. These codes are advantageous in that the same syndrome generator can by used to generate both write and read syndromes. Hamming codes further have the advantage that the read syndrome can directly indicate the location of the bit in error. This simplifies the ECC correction circuit to just the logic needed to toggle or flip the indicated bit in error and enables correction to occur in a single clock cycle. However, Hamming codes are limited in that they are only able to correct a single bit. Hamming codes are disclosed in greater detail in Lin and Costello, Error Control Coding: Fundamentals and Applications, 1983 ISBN 0-13-283796-X, Chapter 3.

ECC systems for semiconductor memory can be divided in to two categories: multi-chip systems and on-chip systems. In a multi-chip system, the ECC system is implemented in more than one chip. Typically these systems are divided so that the ECC circuits, that is the syndrome generators and the correction subsystem, are implemented in a different chip or chips than the semiconductor memory. Multi-chip systems typically use the ECC circuits to protect data stored in multiple semiconductor memory chips. Multi-chip ECC systems are typically employed where semiconductor memory is used as a storage subsystem, such as in a flash memory card.

In the other category of ECC systems for semiconductor memory, the on-chip systems category, all the ECC circuits reside on the same chip as the semiconductor memory. Semiconductor memory using on-chip ECC is well suited to being embedded in a system, where a low number of memory chips are used. On-chip ECC systems benefit from implementations that use small ECC circuits, which minimizes the amount the memory chip area consumed by the ECC function and thus minimizes the cost of the chip.

Many on-chip semiconductor memory ECC systems use small ECC codewords. These small ECC codewords correspond to a groups of data bits that are less than 64 bits, and typically 1, 2, or 4 bytes (8, 16, or 32 bits) in length. A small ECC codeword makes it practical for the write syndrome generator to be implemented using only combinational logic. This allows ECC codewords to be encoded in parallel, that is, not requiring sequential logic and therefore not requiring additional clock cycles. Typically these ECC systems use a Hamming code, which allows the ECC codeword to be decoded in parallel as well (note that ECC codeword decode includes correction in the case of an error). A memory chip having an on-chip ECC system with parallel encode and decode requires no additional clock cycles on writes and reads, which allows the memory chip to operate at the interface in the same way as a conventional memory chip that does not use ECC. While such chips can be easily implemented by a designer into an application, the amount of combinational logic required makes the use of parallel encode and decode only practical with small ECC codewords.

An example of a small codeword, on-chip ECC system for semiconductor memory is disclosed in U.S. Pat. No. 5,765,185, issued Jun. 9, 1998 to Lambrache et al. The semiconductor memory described is EEPROM, and the device has a serial interface. Three small ECC codeword sizes are discussed: a 12 bit ECC codeword that encodes 8 data bits with 4 check bits, a 21 bit ECC codeword that encodes 16 data bits with 5 check bits, and a 38 bit ECC codeword that encodes 32 data bits with 6 check bits. Note that Lambrache et al. refer to check bits in the ECC codeword as parity bits. The ECC system uses a Hamming code and incorporates parallel encode and decode.

Unfortunately, ECC systems with small codewords have a significant disadvantage. The relatively large number of check bits compared to the number of data bits in each ECC codeword requires a substantial portion of the memory array to store them. In the ECC system described in Lambrache et al., the percentage of overhead for ECC storage versus data storage in the memory array is 50%, 31% and 18% for data sizes of 8 bits, 16 bits, and 32 bits respectively. These high overheads increase the chip size and therefore significantly increase the cost of adding ECC function to semiconductor memory. While the use of larger ECC codewords will decrease the overhead required, the amount of combinational logic required to implement the parallel encode and decode for the larger ECC codewords increases. The increased amount of combinational logic requires more chip area and increases fabrication cost.

An on-chip ECC system for semiconductor flash memories that uses multiple parallel large ECC codewords is disclosed in an article by Toru Tanzawa et al., A Compact On-Chip ECC for Low Cost Flash Memories, IEEE Journal of Solid-State circuits, Vol. 32, No. 5, May 1997. The ECC system described uses a Hamming code that can detect up to two bits in error and correct one bit in error. A large 522 bit ECC codeword, made up of 512 data bits and 10 ECC check bits, is used to keep the storage overhead low, at just under 2%. The memory is organized into blocks of 522 bytes, each block consisting of eight parallel 522 bit ECC codewords. One codeword consists of the first bit of each of the 522 bytes, a second codeword consists of the second bit of each of the 522 bytes, and so forth. The 512 data bits contained in each codeword, and the eight parallel codewords, allow each block to contain 512 bytes of data. Each of the eight parallel 522 bit ECC codewords is operated upon by one ECC system. The eight ECC systems operate at the same time, so that all eight can be viewed as a single ECC system.

Tanzawa et al. mentions three different approaches to implementing the ECC systems for the 522 bit codeword: parallel processing ECC, serial processing ECC with buffer, and serial processing ECC without buffer. The chip area overhead required to implement the parallel processing ECC system is 43%, which is very high. The serial ECC systems use less chip area, with an overhead of 17% for the serial processing ECC with buffer, and an overhead of 2% for the serial processing ECC without buffer. The difference in chip overheads resulting from the area required for the buffer.

The ECC system disclosed by Tanzawa et al. suffers from at least two drawbacks. The first of these is the use of multiple ECC codewords to protect the data. Consider for purposes of comparison the approach disclosed in Chapter 3 of the aforementioned Lin and Costello reference, which discloses that 512 bytes (4096 bits) of data can be protected by a Hamming code with single bit correction capability using only 13 check bits, provided that a single ECC codeword is used. In contrast, the eight parallel ECC codewords in the Tanzawa et al. system require the use of 80 check bits to achieve single bit correction, which is more overhead for the same correction capability.

The second major drawback of the parallel processing ECC system disclosed by Tanzawa et al. is the reliance on a code that only can only guarantee correcting a single bit. The use of larger ECC codewords increases the chance of multiple errors occurring within a codeword. If multiple errors occur in an ECC system with only single bit correction capability, the data is not recoverable. The use of eight parallel ECC codewords by Tanzawa et al. allows for the correction of some multiple bit errors, as long as each of the errors fall within a different codeword. Unfortunately, if there are even just two errors, the chance that the second error falls within the same codeword as the first error is 1 in 8, or 12.5%. This means that 12.5% of all two bit errors are not correctable by this ECC system.

Another on-chip flash memory ECC systems that uses a single large ECC codeword is disclosed in U.S. Pat. No. 6,359,806, which issued to Nozoe et al. on Mar. 19, 2002. In this system, each codeword contains 2106 data bytes, including both data and management bytes, and 36 check bits. Hence, the codeword size 2109.5 bytes (16,884 bits) and the memory overhead for the ECC check bits is only 0.2%. The disclosed ECC system uses a Reed-Solomon code which can correct any single byte error within a codeword. Reed-Solomon codes organize ECC codewords into multiple bit symbols. All calculations are based upon these symbols, and the system detects and corrects entire symbols in error. In the Nozoe et al. system, a symbol size of 12 bits is used. Four bits of each symbol are filled by pad “0” bits, so each ECC symbol contains one byte of the codeword. Because of the use of a Reed-Solomon code, if a single bit error occurs, the ECC system must correct the entire byte containing the bit in error, and not just the bit in error.

In many respects, the Tanzawa et al. and the Nozoe et al. systems operate in a similar fashion. Both systems consist of a syndrome generator that functions as both write syndrome generator and read syndrome generator, a flash memory storage array, and ECC correction logic. During write operations, data is delivered sequentially in bytes to the chip and stored in the storage array. In parallel (at the same time), the data bytes are processed by the write syndrome generator to calculate the write syndrome. After the last data byte is stored, the write syndrome is stored to form an ECC codeword within the storage array. On reads, the codeword is removed from the storage array a byte at a time. Each byte is processed by the read syndrome generator. At the end of the codeword, the resulting read syndrome is examined to detect the presence of errors. If an error is detected, the read syndrome is used to correct the data as it is transferred off the chip during a second read from the storage array. During this second read, the data bytes from the storage array are not input into the syndrome generator. The read syndrome that resulted from the first read is left in the syndrome generator, and is processed once for each data byte that is transferred out of the chip. This processed read syndrome is examined before each data byte is transferred to see if that byte contains the error, and if does, to correct it.

The Tanzawa et al. and the Nozoe et al. ECC systems differ in how they handle the second read from the memory array. The Tanzawa et al. system does not transfer off the device the data from the first read from the memory array, as it is unknown until the end of the read if the data is valid. This system therefore always reads two times, even if there is no error, and therefore adds an “unnecessary” delay to the delivery of valid data. The Nozoe et al. system always transfers the data from the first read. At the end of the first read, the read syndrome is evaluated, and the device reports the status over the interface. If there was no error, the data transferred over the interface is valid, there is no second read from the memory array, and the operation is completed. If there was an error, a second read is performed and the data is corrected as it is transferred off the device. In the best case situation, the first data read is correct, and there is no overhead. In the case of a single error, then the data must be read from the device twice before receiving accurate data. In the worst case, the data is read twice, and bad data is received twice. In order for a application to use this device properly, the system reading the device must have a 2048 byte buffer to receive data before processing it; otherwise, erroneous data will be processed.

While large codewords are advantageous in semiconductor memories with on-chip ECC systems because of their low overhead, conventional large codeword systems such as disclosed in the Tanzawa et al. and Nozoe et al. patents are not extendable to multiple bit correction. Read syndromes are not directly generated in large ECC codeword semiconductor memory systems because the amount of combinational logic that would be required would be impractically large. Instead, conventional large codeword systems process the codeword sequentially or iteratively to generate the read syndrome. Unless a Hamming code is used (which can be decoded in parallel), large ECC codeword systems also decode the read syndrome (i.e. determine the location of the errors within the ECC codeword from the read syndrome, so that correction may occur) using sequential or iterative processing. This iterative processing is performed synchronously with transferring the data off the chip. The read syndrome is processed once per byte transferred, so that the processed syndrome corresponds to the current byte being transferred. The correction circuitry checks the processed syndrome to see if it corresponds to a codeword with single error located in the current byte. Correction is performed when there is a match. For multiple error correction, the read syndrome will be determined by the location of both errors. Even if the read syndrome is processed so that it corresponds an error in the current byte being transferred, the processed syndrome will still depend on the location of the other error(s). This limits this type of ECC systems to the correction of single errors.

Multiple error correction ECC systems have been used in some larger density flash memory systems. These ECC systems are distributed onto multiple chips. These systems typically use a Reed Solomon or BCH code. The iterative correction decoding is typically performed by a micro-controller, or a micro-controller augmented by hardware assistance. Because of the complexity and cost of the multiple chip ECC system, the memory array protected by the ECC system is typically large, and is typically composed of an arrangement of multiple high density flash devices. These systems typically report data status to the application before the application receives the data, which allows the application to determine how it will proceed. The application does not need a buffer to buffer error data as in the large density flash system described earlier. An example of a large density flash memory system of this type is described in U.S. Pat. No. 5,291,584, issued Mar. 1, 1994 to Challa et al., and in U.S. Pat. No. 5,410,680, issued Apr. 25, 1995 to Challa et al.

### BRIEF SUMMARY OF THE INVENTION

What is needed is an improved ECC system for semiconductor memory that can implemented at low cost and is suitable for integration onto the memory chip. Such a system should have low overhead, should be based on the detection and correction of individual erroneous bits rather than multiple bit symbols, should detect and correct at least single bit errors, and should be capable of detecting multiple bit errors and supporting correction thereof. Such a system should also be easy to use by the application in that the data error status should be reported before the data is transferred.

Low storage overhead is achieved in some of the embodiments of the present invention by the use of a large ECC codeword in the system. Some of the embodiments of the present invention use relatively simple ECC circuitry (encoder and decoder) that are implemented without using a large amount of the chip area. Some of the embodiments of the present invention use single bit correction techniques rather than multiple bit symbols, such techniques being a suitable match for flash memory systems in which widely separated bit failures, as opposed to the failure of multiple bits within a byte, are the dominant failure mechanism.

Advantageously, each of the various embodiments of the present invention overcomes one or more of the disadvantages of prior approaches, and have one or more of the following properties, possibly among others: (a) efficient integrated hardware correction of single bit errors; (b) support of multiple bit correction; (c) reporting of data status prior to data read; (d) more efficient refresh utilizing the ECC system; (e) small die space relative to many other solutions; (f) extremely small and essentially zero write overhead for ECC syndrome calculation; and (g) optional use of the ECC system.

One embodiment of the invention is an integrated circuit operable in an ECC memory write mode and an ECC memory read mode, comprising a data path disposed in the integrated circuit; a flash memory array disposed in the integrated circuit and coupled to the data path; an ECC circuit disposed in the integrated circuit; and a data interface coupled to the data path for furnishing the first data thereto during the ECC write mode. The ECC circuit is coupled to the data path for creating from first data a single large write codeword using a bit-correcting ECC code during the ECC write mode; and generating a read syndrome from a read codeword using the bit-correcting ECC code during the ECC read mode.

Another embodiment of the invention is an integrated circuit operable in an ECC memory write mode and an ECC memory read mode, comprising a data path disposed in the integrated circuit; a flash memory array disposed in the integrated circuit and coupled to the data path; an ECC circuit disposed in the integrated circuit; and a bit-serial data interface coupled to the data path for furnishing the first data thereto during the ECC write mode. The ECC circuit is coupled to the data path for creating from first data a single large write codeword during the ECC write mode; and generating a read syndrome from a read codeword during the ECC read mode.

Another embodiment of the invention is a method of correcting erroneous data in an integrated circuit having a flash memory array, comprising receiving binary data; creating a single large codeword from the data with a bit-correcting ECC code; programming the codeword into the flash memory array; reading the codeword from the flash memory array; generating a read syndrome from the codeword read in the reading step; evaluating the read syndrome to determine a condition of the codeword read in the reading step; and when the codeword condition is an error condition, attempting to correct the error condition internally in the integrated circuit as determined by the read syndrome.

Another embodiment of the invention is a method of storing user data in and retrieving user data from a nonvolatile page-mode memory array disposed in an integrated circuit and having a plurality of pages of a common size, comprising determining within the integrated circuit a single ECC codeword from successive bits of data using a bit-correcting ECC code, the ECC codeword being of a size equal or substantially equal to the page size and comprising the data and a write syndrome; storing the ECC codeword in a page of the nonvolatile memory array by page mode programming; reading the ECC codeword from the page of the flash memory array; calculating within the integrated circuit a read syndrome from the ECC codeword read in the reading step; and performing within the integrated circuit an error trapping operation using the read syndrome.

Another embodiment of the invention is a method of storing user data in and retrieving user data from a flash memory array that is part of a serial flash integrated circuit, comprising calculating a write syndrome in the serial flash integrated circuit from successive bits of the user data with a bit-correcting ECC code; storing the user data and the ECC write syndrome in a page of the flash memory array as an ECC codeword; reading the ECC codeword from the page of the flash memory array to a volatile memory having essentially a page of storage capacity, the volatile memory being part of the serial flash integrated circuit; calculating a read syndrome from the ECC codeword read in the reading step; detecting a one bit error and location information therefor from the read syndrome; and correcting the one bit error in the volatile memory by use of the location information.

Another embodiment of the invention is a method of correcting erroneous data in an integrated circuit having a flash memory array, comprising receiving binary data in bit-serial form; creating a single large codeword from the data; programming the codeword into the flash memory array; reading the codeword from the flash memory array; generating a read syndrome from the codeword read in the reading step; evaluating the read syndrome to determine a condition of the codeword; and when the codeword condition is an error condition, attempting to correct the error condition internally in the integrated circuit as determined by the read syndrome.

Another embodiment of the invention is an integrated circuit operable in an ECC memory write mode and an ECC memory read mode, comprising a data path disposed in the integrated circuit; a data interface coupled to the data path for furnishing data thereto during the ECC write mode; a flash memory array disposed in the integrated circuit and coupled to the data path; and a bit-correcting sequential ECC correction engine disposed in the integrated circuit and coupled to the data path for sequentially receiving the data in bit-serial fashion and furnishing a write codeword derived from the data during the ECC write mode; and sequentially receiving a read codeword, furnishing an error status indication based at least in part on an evaluation of a read syndrome derived from the read codeword during the ECC read mode, and correcting an error condition in the read codeword.

Another embodiment of the invention is an integrated circuit comprising a data path disposed in the integrated circuit; a bit-serial interface disposed in the integrated circuit and coupled to the data path; a flash memory array disposed in the integrated circuit and coupled to the data path; and a sequential correction engine having a bit-serial coupling to the data path, the correction engine using a bit-correcting ECC code to create a codeword and to generate a read syndrome from a codeword.

Another embodiment of the invention is a method of correcting erroneous data in an integrated circuit having a flash memory array, comprising receiving binary data in the integrated circuit; sequentially processing bits of the data with a bit-correcting ECC code in the integrated circuit to create a codeword; programming the codeword into the flash memory array; reading the codeword from the flash memory array; sequentially processing the codeword read in the reading step with the bit-correcting ECC code in the integrated circuit to generate a read syndrome; evaluating the read syndrome to determine a condition of the codeword; and when the codeword condition is an error condition, sequentially processing the codeword read in the reading step as determined by the read syndrome in an attempt to correct the error condition internally in the integrated circuit.

Another embodiment of the invention is a method of refreshing a flash memory array that is part of an integrated circuit, comprising reading an ECC codeword from a page of the flash memory array to a volatile memory having essentially a page of storage capacity, the volatile memory being part of the integrated circuit; calculating a read syndrome from the ECC codeword, in the integrated circuit; detecting an error condition in the ECC codeword and location information therefor from, at least in part, the read syndrome, in the integrated circuit; correcting the error condition in the ECC codeword residing in the volatile memory by use of the location information, in the integrated circuit, to obtain a corrected ECC codeword having one or more corrected bit or bits; and writing at least the corrected bit or bits of the corrected ECC codeword from the volatile memory to a page of the flash memory array.

Another embodiment of the invention is a method of refreshing a flash memory array that is part of an integrated circuit, comprising reading an ECC codeword from a page of the flash memory array; calculating a read syndrome from the ECC codeword, in the integrated circuit; detecting an error condition in the ECC codeword and location information therefor from, at least in part, the read syndrome, in the integrated circuit; correcting the error condition in the ECC codeword, in the integrated circuit, to obtain an ECC codeword having one or more corrected bit or bits; and writing at least the corrected bit or bits of the ECC codeword to a page of the flash memory array.

Another embodiment of the invention is a method of obtaining data from the flash memory array of an integrated circuit, comprising reading a plurality of ECC codewords from respective pages of the flash memory array in the integrated circuit, each of the ECC codewords comprising a data section and an ECC write syndrome section; generating, in the integrated circuit, respective read syndromes from the ECC codewords, wherein some of the read syndromes indicate no erroneous data and others of the read syndromes indicate erroneous data; attempting correction of the ECC codewords having respective read syndromes indicating erroneous data, in the integrated circuit; for the ECC codewords successfully corrected in the correction attempting step, furnishing the data sections thereof as outputs from the integrated circuit; for the ECC codewords unsuccessfully corrected in the correction attempting step, furnishing information suitable for off-chip recovery of data therefrom as outputs from the integrated circuit; and for the ECC codewords having respective read syndromes indicating no erroneous data, furnishing the data sections thereof as outputs from the integrated circuit.

Another embodiment of the invention is a method of writing to the flash memory array of an integrated circuit, comprising serially receiving first data and a first command to write the first data without error correction; programming a page of the flash memory array with the first data; serially receiving second data and a second command to write the second data with error correction; generating an ECC codeword from the second data; and programming a page of the flash memory array with the ECC codeword.

Another embodiment of the invention is a method of reading the flash memory array of an integrated circuit, comprising serially receiving a first command to read a first page of the flash memory array without error correction; furnishing the first page of the flash memory array as serial output from the integrated circuit; serially receiving a second command to read a second page of the flash memory array with error correction; generating in the integrated circuit a read syndrome from an ECC codeword stored in the second page of the flash memory, the ECC codeword having a data section and a write syndrome section; evaluating the read syndrome in the integrated circuit to detect an error condition in the ECC codeword; correcting the error condition in the ECC codeword as determined by the read syndrome in the integrated circuit to obtain a corrected ECC codeword; and furnishing the data section of the corrected first ECC codeword as output from the integrated circuit.

Another embodiment of the invention is a method of correcting erroneous data in an integrated circuit having a flash memory array, comprising reading a codeword from the flash memory array, the codeword comprising data and a write syndrome; generating a read syndrome in the integrated circuit from the codeword read in the reading step; evaluating the read syndrome to determine whether an error condition exists in the codeword; furnishing the data from the codeword as output from the integrated circuit based on the evaluating step, the data being uncorrected when the evaluating step indicates no error condition, the data being corrected based on the read syndrome when the evaluating step indicates an error condition and the error condition is correctable, and the data being uncorrected when the evaluating step indicates an error condition and the error condition is uncorrectable; and prior to the data furnishing step, furnishing a data status as output from the integrated circuit, the data status being “error free” when the evaluating step indicates no error condition, the data status being “corrected error” when the evaluating step indicates an error condition and the error condition is correctable, and the data status being “uncorrectable error” when the evaluating step indicates an error condition and the error condition is uncorrectable.

Another embodiment of the invention is a serial flash memory integrated circuit comprising a data path; a flash memory array coupled to the data path; a page memory coupled to the data path; a bit-serial input/output interface coupled to the data path; a sequential syndrome generator based on a bit-correcting ECC code having a bit-serial coupling to the data path and an output; and an error trapper having an input coupled to the output of the syndrome generator.

Another embodiment of the invention is a serial flash memory integrated circuit comprising a flash memory array; a page memory coupled to the flash memory array; a shift register coupled to the flash memory array and to the page memory; a bit inverter coupled to the shift register; a bit-serial input/output interface coupled to the shift register; a sequential syndrome generator based on a bit-correcting ECC code and having a bit-serial coupling to the shift register and an output; an error trapper having an input coupled to the output of the syndrome generator; a zero detector coupled to the output of the syndrome generator; a counter; a sequencer coupled to the error trapper, the zero detector, and the counter, and having an error status output coupled to the input/output interface; and address logic having an input coupled to the counter and an output coupled to the bit inverter.

### BRIEF DESCRIPTION OF THE SEVERAL VIEWS OF THE DRAWINGS

FIG. 1 is a block schematic diagram of a serial flash memory containing an ECC system in accordance with the present invention.

FIG. 2 is a pictorial representation of an ECC codeword suitable for the ECC system of FIG. 1.

FIG. 3 is a schematic diagram of an illustrative embodiment of sequencer useful in the ECC system of FIG. 1.

FIG. 4 is a state diagram for the sequencer of FIG. 3.

FIG. 5 is a timing diagram characteristic of an ECC write operation.

FIG. 6 is a timing diagram characteristic of an ECC read operation in which no data errors are found.

FIG. 7 is a timing diagram characteristic of an ECC read operation in which a single bit data error is corrected.

FIG. 8 is a timing diagram characteristic of an ECC read operation with multiple data errors.

FIG. 9A and FIG. 9B in combination is a schematic diagram of a syndrome generator in accordance with the present invention.

FIG. 10 is a block schematic diagram of a SFFC component that is repeatedly used in the syndrome generator of FIG. 9A and FIG. 9B.

FIG. 11 is a block schematic diagram of a SFFP component that is repeatedly used in the syndrome generator of FIG. 9A and FIG. 9B.

FIG. 12 is a block schematic diagram of a SFFL component that is repeatedly used in the syndrome generator of FIG. 9A and FIG. 9B.

FIG. 13A and FIG. 13B in combination is a schematic diagram of an error trapper in accordance with the present invention.

FIG. 14 is a block schematic diagram of a TFF component that is repeatedly used in the syndrome generator of FIG. 9A and FIG. 9B.

### ED DESCRIPTION OF THE INVENTION, INCLUDING THE BEST MODE

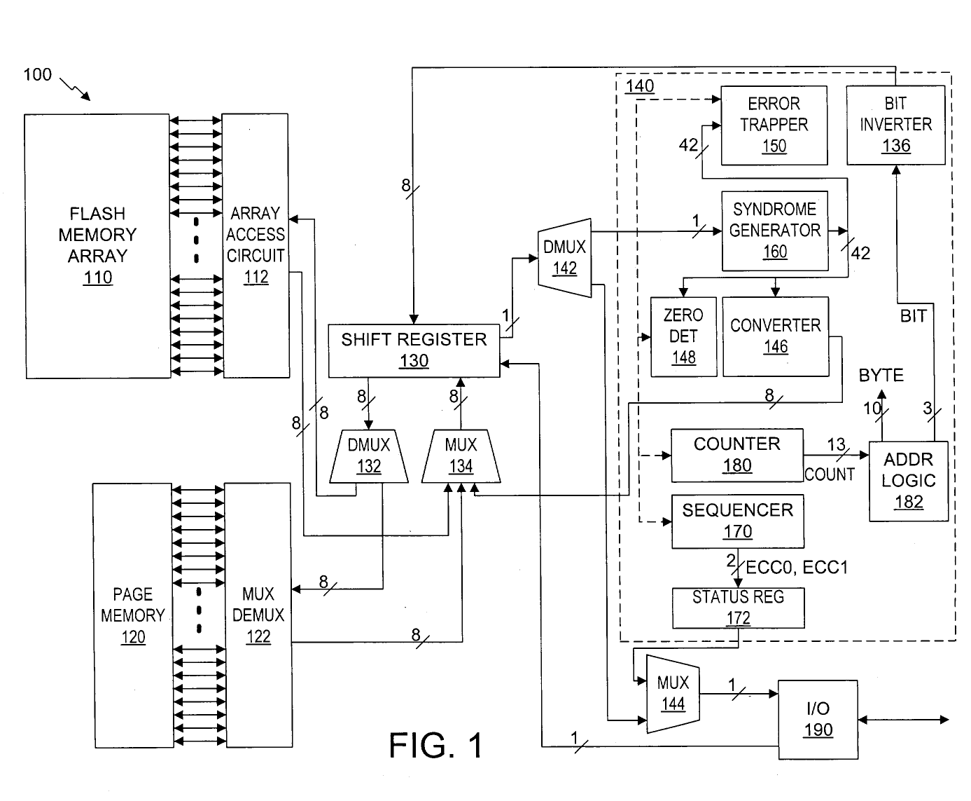

As shown in the illustrative embodiment of FIG. 1, a serial flash memory 100 is provided with an integrated error correction coding (“ECC”) system 140 that is used with an integrated volatile page memory 120 for fast automatic data correction (AutoCorrect). Preferably, the ECC code has the capability of correcting any one or two bit error that occurs in a page between writing and reading. One bit corrections are done automatically in hardware during reads or transfer to the page memory 120 (AutoCorrect), while two-bit corrections are handled in external software, firmware or hardware. The use of ECC is optional, so that command sets may include ECC read and ECC write commands as well as non-ECC read and non-ECC write commands. The serial flash memory 100 also includes any suitable internal data path that is controllably configurable for the various operational modes of the serial flash memory 100. An illustrative data path in FIG. 1 includes the various multiplexers 132, 134, 142 and 144 as well as the shift register 130. Various signal paths and “glue” logic for these paths are omitted from FIG. 1 to avoid unnecessary clutter to the drawing, the design of such elements being a matter of ordinary skill when guided by this detailed description.

The Serial Flash memory 100 illustratively has a “bit-serial” I/O that transfers data through a single data input node and a single data output node, or through a single combined input/output node. Command, address and data information is sequentially clocked in, and data and status is sequentially clocked out. A popular bit-serial interface specification is the Serial Peripheral Interface (“SPI”) protocol, which uses the four signal pins Data In, Data Out, Clock and Chip Select. A “bit-serial” memory is to be distinguished from other types of memory that use multiple data I/Os, such as memory chips that interface to 8-bit or 16-bit data busses. Some NAND flash memory chips, for example, are occasionally referred to as serial flash but are actually “byte-serial” in that they sequentially clock data in and out through an 8-bit or 16-bit data bus instead of a single data pin. Parallel flash memories also use an 8-bit or 16-bit data bus but typically use address busses for randomly accessing data, rather than sequential clocking.

Advantageously, the bit-serial ECC architecture of the ECC system 140 is complementary to a bit-serial flash memory I/O. Even as supplemented with the ECC system 140, the serial flash memory 100 offers a cost-effective storage solution for systems limited in power, pins, space, hardware and firmware resources. Serial flash memory is ideal, for example, in applications that store audio, image, and download-code. An illustrative power requirement for the serial flash memory is a single 2.7V -3.6V power supply for read and erase/write, with typical current consumption as low as 10 mA active and less than 1 uA standby.

Advantageously, the serial flash memory 100 with integrated ECC 140 and page memory 120 provides single bit error correction within the memory and supports multiple bit correction off-chip. The page memory 120 is a volatile memory to support fast reads and writes. Illustratively, the serial flash memory utilizes a 42 bit BCH ECC code, which allows for 3 bit detection and 1 and 2 bit correction. The integrated hardware correction circuit corrects one bit errors in a cost-effective manner. A software, firmware or hardware algorithm can optionally be run in the application to correct two bit errors.

Advantageously, the integrated ECC system 140 for the serial flash memory 100 has a relatively small circuit size and makes efficient use of limited chip space. Preferably, syndrome generation is sequential from bit-serial data, that is, each bit of data is routed to the syndrome generator 160 individually and at high speed. This allows the ECC system to have a smaller circuit size relative to ECC systems that process bits in parallel, since the more bits processed at a time, the larger the circuit required to perform syndrome generation. The ECC system 140 utilizes a circuit called an error trapper 150, which permits correction of a single bit error in 522 bytes and 42 bits. The circuitry for the error trapper 150 is constructed much the same as the circuitry for the syndrome generator 160, insofar as it is a relatively small circuit that makes efficient use of limited chip space.

Advantageously, the timing of internal clock cycles can be substantially increased relative to the external clock to provide very fast 1 bit correction. Each bit of data is routed to the syndrome generator 160 individually and at high speed. In the error trapper 150, the correction latency is between 1 and 4218 internal clock cycles.

Advantageously, the serial flash memory 100 makes the data status available before the data. This allows the application to efficiently plan for data errors with corrective action that makes sense for the application. Some applications will refresh data based on errors, some applications will relocate blocks based on errors, and yet other applications are tolerant of single or multiple bit errors and will ignore status. Making the data status available prior to the data also avoids the need to buffer the data in the application pending its status, such buffering generally being unavailable in small applications.

Advantageously, use of ECC in the serial flash memory 100 is optional. ECC systems are particularly useful to combat memory disturb in flash memories used for random write applications, but may be unnecessary in flash memories used for sequential write applications and for error-tolerant applications. Although the latency experienced during correction in the serial flash memory is quite small in relation to some prior ECC circuit designs, users designing applications that are not particularly error-sensitive or that use mainly sequential transfers may elect to not use ECC to avoid such latency delays as might be introduced by the ECC system. Moreover, if ECC is not used, the data cells otherwise required for ECC storage are made available to the application for other uses.

Advantageously, the serial flash memory 100 has a smart refresh capability using an integrated page memory and the integrated ECC system 140. Smart refresh allows for a refresh system based on reading the flash array in the background to detect memory disturb errors. When a disturb error occurs, the page or static data areas can then be refreshed from the corrected data in the page memory. This algorithm accommodates the manufacturing tolerance of the data cells and refreshes only when the data cells require refresh. In essence, the device is giving the application an intelligent signal for refreshing static areas.

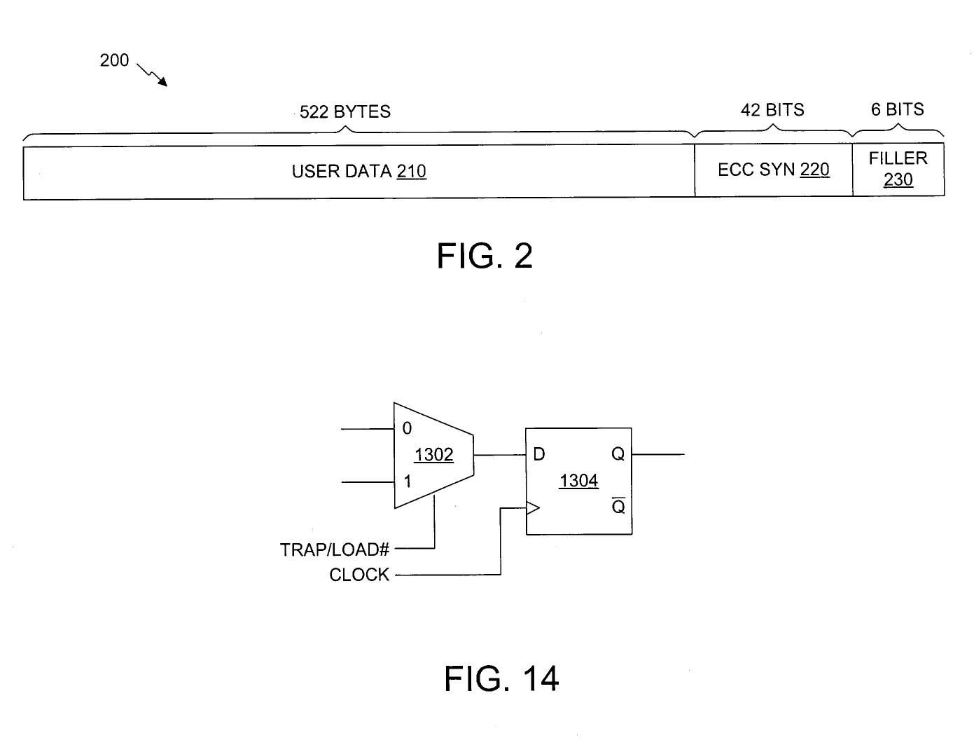

FIG. 2 shows the contents of an illustrative page of memory when the ECC option is enabled. The page has 4176 bits (522 bytes) of original user data 210, 42 bits of check bits 220, and 6 bits of filler 230. The user data 210 and the check bits 220 form an ECC codeword 200. The user application utilizes the user data portion of the codeword 200. Although the use of an ECC code that causes the user data to appear as the first part of the ECC codeword is preferred, other ECC codes having other properties may be used if desired, with the appropriate hardware modifications, including those that generated ECC codewords in which the user data may not be identifiable.

The ECC hardware 140 generates the ECC codeword 200 from original user data during memory writes. Preferably, this is accomplished by generating the check bits 220 from the user data 210 and appending the check bits 220 to the user data 210. During reads, the ECC codeword 200 is retrieved from the flash memory array 110 and stored in the page memory 120. The ECC codeword 200 is processed by the ECC hardware 140, which detects the presence of errors within the ECC codeword 200. If no errors are detected, the user data 210 is transferred out to the application without change. If an error capable of correction by the ECC hardware 140 is detected, the erroneous data bit or bits are inverted preferably in the page memory 120, and the corrected user data is then transferred out to the application. If the ECC hardware 140 detects an error that it determines exceeds its correction capability, sufficient information is passed to the application to enable it to perform more powerful correction and to recover the user data 210, if so desired.

The ECC hardware 140 contains a syndrome generator 160. During writes, the syndrome generator 160 is used to calculate the check bits 220, which are also known as the write syndrome, from the user data 210. The check bits 220 are appended to the user data 210 to form the written ECC codeword 200. Advantageously, the same syndrome generator 160 is used during reads, when the ECC codeword 200 retrieved from the flash memory array 110 is fed to the syndrome generator 160, which calculates a read syndrome. The read syndrome is evaluated. If the read syndrome is zero, as determined in zero detector 148, no error occurred within the ECC codeword 200 and the user data 210 is transferred out “as is.” If the read syndrome is non-zero, as determined in the zero detector 148, an error condition is detected and the read syndrome is transferred to a correction subsystem, which may include, for example, an error trapper 150. The correction subsystem sequentially processes the read syndrome. If the error is within the correction subsystem's capability to correct, the location of the bit or bits in error are determined by the correction subsystem. These bits are then corrected in the page memory 120. If the correction subsystem determines that it can not correct the ECC codeword 200, the user data 210 and the read syndrome 220 are transferred to the application, wherein a correction subsystem with more correction capability may be employed.

The write codeword preferably but not necessarily contains a literal copy of the data. For an embodiment in which the write codeword does not contain a literal copy of the data, the syndrome generator may be viewed as an encoder for purposes of generating the write codeword. When the write codeword is read, the read codeword may be passed through the read syndrome generator, the resulting syndrome may be used to correct the read codeword, and the corrected read codeword may be passed through a decoder to obtain the user data. Alternatively, user data and the read syndrome may be obtained from the read codeword, and the resulting syndrome may be used to correct the user data obtained from the read codeword.

The syndrome generator 160 preferably is based on an ECC code capable of correcting at least two errors. Preferably large ECC codewords greater than about 64 bits are used, which have low storage overhead requirements and still provide sufficient reliability improvement. The ECC hardware 140 also preferably contains a correction subsystem that can automatically correct at least one error. If no automatic correction capability is provided by the ECC hardware 140, then all errors must be corrected by the application at a substantial access time penalty. Access time performance may be improved by requiring higher reliability from the memory cells within the flash memory array 110, which somewhat undermines the motivation behind using an ECC system with the flash memory. Preferentially, the application will provide the capability of additional correction made possible by the ECC code that is not provided by the ECC hardware 140. The correction subsystem of the application may be implemented in software or firmware at relatively little cost, but at the risk of incurring a significant time penalty when employed. Even so, the dual correction ECC system wherein the ECC hardware 140 provides the syndrome generator 160 some degree of correction capability in hardware, and the application provides additional correction capability, is highly advantageous. The correction capability of the ECC code advantageously is chosen to satisfy the reliability required of the ECC system, but the ECC hardware 140 need not implement all of this correction capability and can therefore be significantly simpler in design than if it were to implement all of the correction capability. What correction capability is implemented in the ECC hardware 140 is determined by the frequency of occurrence of multiple error events and the access time requirements of the memory system.

As shown in FIG. 1, the ECC hardware 140 illustratively and preferably has an error trapper 150, a sequencer 170, and a counter 180. The error trapper 150 implements the error trapping method, which is capable of correcting a single error within an ECC codeword with relatively little circuitry. The sequencer 170 supervises the timing and sequence of the correction process.

Upon detection of a non-zero read syndrome in the syndrome generator 160, the read syndrome is transferred to the error trapper 150. There, the read syndrome is sequentially processed under control of the sequencer 170 to see whether it corresponds to a single error in each location within the ECC codeword 200. The counter 180 keeps track of which location within the codeword is being evaluated. If the error trapper 150 determines that the read syndrome being processed corresponds to an error, the counter 180 contains the location of the error. If an error is located, the location within the page memory 120 indicated by the counter 180 is corrected. If no error is located, and the sequencer 170 detects that the end of the ECC codeword has been reached, the sequencer 170 stops the correction process and indicates that correction subsystem is unable to correct the codeword. The uncorrected user data and the unprocessed read syndrome are then transferred to the application for further processing.

Although single bit error correction is sufficient for many practical applications, the correction subsystem within the ECC hardware 140 could be made capable of multiple error correction if so desired, albeit through the use of additional circuitry and therefore at a correspondingly higher cost.

Preferably the ECC hardware 140 implements an ECC code suitable for the correction of individual bits, as opposed to symbols. Such ECC codes match the predominant failure mechanisms within the flash memory array 110, whereby errors occur randomly in one or more individual bits of a page and not in groups of bits.

Preferably, the ECC code is a cyclic code. Cyclic codes allow data to be treated as polynomials and therefore allow syndromes to be generated by performing polynomial division. The ability to use polynomial division allows the syndrome generation logic for even a large ECC codeword to require relatively little logic circuitry. Cyclic codes are discussed in further detail in Chapter 4 of the work by Shu Lin and Daniel J. Costello, Jr. entitled Error Control Coding: Fundamentals and Applications, Prentice Hall, ISBN 0-12-283796-X, 1983, the work being hereby incorporated herein by reference in its entirety.

Preferably, the ECC hardware 140 is based upon a BCH code. A BCH code is cyclic, corrects individual bits, and is capable of correcting multiple bits in error. BCH codes are based upon Galois Field algebra, enabling the decoding and correction of multiple bit errors to be based upon an algorithmic process and thus be performed in a reasonably short amount of time.

As discussed in further detail in Chapter 6 of the aforementioned work by Lin and Costello, Jr., if the number of bits in each element of the Galois field is n, then the ECC codeword for a BCH code can be no larger than 2ⁿ-1 bits in length. Because a large ECC codeword size of 4204 bits is being used, (to reduce the amount of storage overhead required), the minimum element size of the Galois Field is 13 bits. A Galois Field with 13 bit elements is referred to as GF(2¹³). Because it is easier to deal with an even number of bits, and to enable the Galois field to be constructed from a smaller sub-field, the preferred embodiment uses GF(2¹⁴) with 14 bit elements. Nonetheless, in some implementations GF(2¹⁶), with 16 bit elements, may be advantageous. Sixteen bits is exactly two bytes and, in some implementations, may simplify the logic circuitry but may result in larger tables being used in the correction subsystem because of the larger element size.

Moreover, the order of the generator polynomial of the BCH code will be a multiple of n, where n is the number of bits in the elements of the Galois field. The order of the generator polynomial determines the number of bits in the write and read syndromes. The order of the generator polynomial also determines the number of check bits 230. The BCH code can correct one error for every n bits in the syndromes (and check bits). The preferred BCH code can correct two errors and is based on GF(2¹⁴) with 14 bit elements and n=14. Thus, a 28^{th} order generator polynomial could be used, with 28 bits of check bits. However, while such a code would always correct any two bits in error, it would mistakenly attempt to correct about 3% of errors that contain three or more bits and cause corrupted data to be indicated as valid. To reduce this probability, preferably a BCH code is used with inherent three bit correction capability, but its use is restricted to two bit correction. Therefore, preferably a 42^{nd} order generator polynomial is used, with 42 bit write and read syndromes, and 42 bits of check bits. If desired, the ECC system could be designed to correct more than two bits in error if a BCH code with greater correction capability were used. However, such a design would result in an increase in generator polynomial order, syndrome sizes, and in the number of check bits.

Galois fields, which are also known as finite fields, are described in further detail in Chapter 2 of the aforementioned work by Lin and Costello, Jr. The non-zero elements of a Galois field are traditionally represented as powers of α. For the Galois field GF(2¹⁴), the field would be composed of the elements {0, α⁰, α¹, α², α³, . . . , α^{65,534}}. The largest power of α is 65,534=2¹⁴−2, and there are 65,536=2¹⁴ elements comprising the field. A Galois field can be created using a primitive binary polynomial, that is a primitive polynomial based upon the binary Galois field GF(2). The order of this primitive polynomial is the number of bits in the elements of the Galois field that it creates. Thus, the Galois field GF(2¹⁴) that is used in the preferred embodiment could be created using a binary primitive polynomial of order 14.

In practice, performing calculation on elements of a Galios field, such as is involved when performing multiple bit correction using a BCH code, requires tables containing entries for all the elements in the field. As the field GF(2¹⁴) contains 65,536 elements, these tables would require a substantial amount of memory. To avoid the need for all of this memory, preferably a Galois field GF(2¹⁴) is created from a smaller Galois field GF(2⁷). The smaller field is referred to as the subfield, and the larger field that is created from it is referred to as the extension field. By basing the BCH code upon an extension field created from a smaller subfield, the required tables can then be constructed based on the size of the subfield. If the Galois field GF(2⁷ ) is used as the subfield to create the extension field GF(2¹⁴), the tables can be constructed so that they contain only 128 entries instead of 65,536 entries.

Any Galois field GF(2⁷) can serve as the subfield. To differentiate the elements of the subfield from those of the larger extension field GF(2¹⁴), the non-zero elements of the subfield GF (2⁷) will be represented by powers of p (the Greek letter Ro). The powers of α (the Greek letter Alpha) will represent for the non-zero elements of the larger extension field GF(2¹⁴). The subfield GF(2⁷) therefore contains the following 128 elements {0, ρ⁰, ρ¹, ρ², ρ³, . . . , ρ¹²⁶}. The subfield GF(2⁷) was created using the binary primitive polynomial x⁷+x⁵+x⁴+x³+1. The first few elements of this field are listed below. The determination of the remaining elements of the subfield is described in Chapter 2 of the aforementioned work by Lin and Costello, Jr.

| | | | | | | | |
|---|---|---|---|---|---|---|---|
| 0 | 0 | 0 | 0 | 0 | 0 | 0 | 0 |
| ρ⁰ | 0 | 0 | 0 | 0 | 0 | 0 | 1 |
| ρ¹ | 0 | 0 | 0 | 0 | 0 | 1 | 0 |
| ρ² | 0 | 0 | 0 | 0 | 1 | 0 | 0 |
| ρ³ | 0 | 0 | 0 | 1 | 0 | 0 | 0 |
| ρ⁴ | 0 | 0 | 1 | 0 | 0 | 0 | 0 |
| ρ⁵ | 0 | 1 | 0 | 0 | 0 | 0 | 0 |
| ρ⁶ | 1 | 0 | 0 | 0 | 0 | 0 | 0 |
| ρ⁷ | 0 | 1 | 1 | 1 | 0 | 0 | 1 |
| ρ⁸ | 1 | 1 | 1 | 0 | 0 | 1 | 0 |

Each element of the extension field GF(2¹⁴) can be considered to be a first order polynomial with coefficients that are elements of the subfield GF (2⁷). Thus, if α^{k} is any element of the extension field, and c₀ and c₁ are elements of the subfield:

α^{k}=c₁·x+c₀

The extension field is constructed from a primitive polynomial based upon the subfield. In the preferred embodiment, the primitive polynomial used is:

p(x)=x²+x+ρ¹⁰

The primitive element of a Galois field α is always a root of the primitive polynomial that is used to construct the field. Therefore, α is a root of p(x) and therefore p(α)=0. Subsituting this into the equation for p(x) above, and noting that subtraction in binary fields is the same as addition, yields:

p(α)=α²+α+ρ¹⁰=0

[symbol]

α²=α+ρ¹⁰

Using this relation, the extension field can be constructed. The first element of the extension field is chosen to be a primitive first order polynomial, α¹=x+0. The remaining elements in the extension field are constructed by applying the relationship derived above.

α¹=x+0 c₁=1=ρ⁰ c₀=0

$$\begin{matrix}\begin{matrix}{α}^{2} = α + {ρ}^{10} = ( x + 0 ) + {ρ}^{10} = x + {ρ}^{10} \\ {α}^{3} = {α}^{1} \cdot {α}^{2} = {α}^{1} \cdot ( α + {ρ}^{10} ) = {α}^{2} + {ρ}^{10} \cdot {α}^{1} \\ = ( α + {ρ}^{10} ) + {ρ}^{10} \cdot {α}^{1} = ( 1 + {ρ}^{10} ) \cdot {α}^{1} + {ρ}^{10} \\ = ( 1 + {ρ}^{10} ) \cdot x + {ρ}^{10}\end{matrix} & \begin{matrix}{c}_{1} = 1 = {ρ}^{0} \\ {c}_{1} = 1 + {ρ}^{10} \\ {c}_{1} = {ρ}^{0} + {ρ}^{10}\end{matrix} & \begin{matrix}{c}_{0} = {ρ}^{10} \\ {c}_{0} = {ρ}^{10} \\ \end{matrix} \\ \begin{matrix}{α}^{4} = {α}^{2} \cdot {α}^{2} = ( α + {ρ}^{10} ) \cdot ( α + {ρ}^{10} ) \\ = {α}^{2} + {ρ}^{10} \cdot α + {ρ}^{10} \cdot α + {ρ}^{20} = {α}^{2} + {ρ}^{20} \\ = ( α + {ρ}^{10} ) + {ρ}^{20} = x + ( {ρ}^{10} + {ρ}^{20} )\end{matrix} & \begin{matrix}{c}_{1} = 1 = {ρ}^{0} \\ \\ \end{matrix} & \begin{matrix}{c}_{0} = {ρ}^{10} + {ρ}^{20} \\ \\ \end{matrix}\end{matrix}$$

The binary representation of an extension field element is formed by concatenating the binary representations of the two coefficients c₁ and c₀. Thus, the first few elements of the extension field from GF(2¹⁴) are:

| | | | | | | | | | | | | | | |
|---|---|---|---|---|---|---|---|---|---|---|---|---|---|---|
| 0 | 0 | 0 | 0 | 0 | 0 | 0 | 0 | 0 | 0 | 0 | 0 | 0 | 0 | 0 |
| α⁰ | 0 | 0 | 0 | 0 | 0 | 0 | 0 | 0 | 0 | 0 | 0 | 0 | 0 | 1 |
| α¹ | 0 | 0 | 0 | 0 | 0 | 0 | 1 | 0 | 0 | 0 | 0 | 0 | 0 | 0 |
| α² | 0 | 0 | 0 | 0 | 0 | 0 | 1 | 0 | 0 | 0 | 0 | 0 | 1 | 1 |
| α³ | 0 | 0 | 0 | 0 | 0 | 1 | 0 | 0 | 0 | 0 | 0 | 0 | 1 | 1 |
| α⁴ | 0 | 0 | 0 | 0 | 0 | 0 | 1 | 0 | 0 | 0 | 0 | 1 | 1 | 0 |

A 3 bit correcting BCH code can be constructed using the extension field GF (2¹⁴) derived above, in the manner described in Chapter 6 of the aforementioned work by Lin and Costello, Jr. The resulting generator polynomial for the BCH code is:

x⁴²+x³⁹+x³⁸+x³⁶+x³³+x³²+x³¹+x²²+x²¹+x²⁰+x¹⁹+x¹⁶+x¹⁵+x¹²+x¹¹+x¹⁰+x⁸+x⁷+x⁵+x¹+x⁰ (1)

The syndrome generator 160 implements this generator polynomial, as does the error trapper 150.

The ECC system 140 performs an ECC write operation using a command “Write Main Array Page with ECC” in the following illustrative manner. User data is clocked into an 8 bit shift register 130 from the I/O interface 190 one bit at a time. When a byte of data is received by the shift register 130, the byte is written to the appropriate byte of the page memory 120 through a demultiplexer 132 and the multiplexer/demultiplexer 122. This process is repeated for all 522 bytes of the user data 210. Next, the data in the page memory 120 is copied byte-by-byte into the shift register 130, from which it is directed to the flash memory array 110 through the demultiplexer 132 and the array access circuit 112, and also shifted bit-by-bit into the syndrome generator 160 through the demultiplexer 142. The syndrome generator 160 performs a mathematical computation on the user data 210 bit-by-bit, computing the check bits 220 while the user data 210 is being clocked in. When the last data bit of the user data 210 has been clocked in, the check bits 220 are complete and are preserved at the output of the syndrome generator 160 until the next ECC command is issued. The check bits 220 are then written to the page memory 120 byte-by-byte, starting at the 523^{rd} byte of the page memory 120. A converter 146, which illustratively is an 8×6 array of gates, sequentially selects each of the syndrome bytes, which is written to the page memory 120 from the converter 146 through a multiplexer 134, the shift register 130, a demultiplexer 132, and the multiplexer/demultiplexer 122. The last byte contains two of the check bits 220 and six dummy or filler bits 230, illustrative assigned a value of “1.” The six bytes of the check bits 220 are then directed to the flash memory array 110 through the multiplexer/demultiplexer 122, the multiplexer 134, the shift register 130, the demultiplexer 132, and the array access circuit 112.

It will be appreciated that the “Write Main Array Page with ECC” operation entails very little overhead. For each byte of user data 210, eight clocks are needed to shift bits into the syndrome generator 160, and after all user data 210 has been received, a further 48 clocks are used to write the ECC syndrome from the syndrome generator 160 to the page memory 120. However, as the time required for these ECC-related functions is on the order of microseconds compared to the milliseconds required for programming the flash memory array 110, it is negligible.

Any overhead entailed by the “Write Main Array Page with ECC” operation is minimized by clocking the internal circuitry of the flash memory 100, including the ECC system 140, at a faster clock rate than the input and output is clocked. For example, an external clock rate of 10 MHz may be used to clock external data into the page memory 120, while an internal clock rate of 20 MHz may be used to clock data from the page memory 120 to the flash memory array 110 and to the syndrome generator 160, and to clock the check bits 220 from the syndrome generator 160 to the page memory 120. It will be appreciated that the internal clock may also be used to clock internal transfers during ECC read operations, thereby speeding up any overhead associated with these operations as well.

It will be appreciated that data may be furnished to the syndrome generator 160 in various alternative ways. In one alternative, just after the present byte in the shift register 130 is written to the page memory 120 and before the next byte is received into the shift register 130, the present byte is shifted out one bit at a time to the syndrome generator 160 through a demultiplexer 142. This process is repeated for all 522 bytes of the user data 210.

It will be appreciated that data may be directed to the flash memory array 110 as it is being received, rather than through the page memory 120. In one alternative, data is directed from the shift register 130 to both the flash memory array 110 and the page memory 120. In another alternative, the ECC syndrome is directed to the flash memory array 110 and is not written to the page memory 120.

The ECC system 140 performs write operation without ECC using a command “Write Main Array Page without ECC” in the following manner. User data is clocked into the 8 bit shift register 130 from the I/O interface 190 one bit at a time. When a byte of data is received by the shift register 130, the byte is written to the appropriate byte of the page memory 120 through the demultiplexer 122. This process is repeated for 528 bytes of user data, which is the 522 bytes of user data 210 augmented by six bytes otherwise used for the ECC syndrome 220. Next, the data in the page memory 120 is copied byte-by-byte into the shift register 130, from which it is directed to the flash memory array 110 through the array access circuit 112.

The ECC system 140 performs a read operation called “Transfer Main Array Page to Buffer with AutoCorrect” in the following manner. The page of data, which includes user data 210, ECC syndrome 220, and filler bits 230, is transferred from the flash memory array 110 into the page memory 120 through the array access circuit 112, the multiplexer 134, the shift register 130, the demultiplexer 132, and the multiplexer/demultiplexer 122. The page data is copied into the shift register 130 byte-by-byte through the multiplexer/demultiplexer 122 and the multiplexer 134. From the shift register 130, each byte is shifted out bit-by-bit into the syndrome generator 160 through the demultiplexer 142. The syndrome generator 160 performs a mathematical computation for the entire page by computing a 42-bit read syndrome from the user data 210 and the check bits 220. If this read syndrome is zero, no error has occurred in the data and the user data stored in the page memory 120 is valid. The status “error free” is recorded in the status register 172 based on signals ECC0 (correction occurred) and ECC1 (data invalid), and the application detects this status by reading the status register 172 through the multiplexer 144 and the I/O 190.

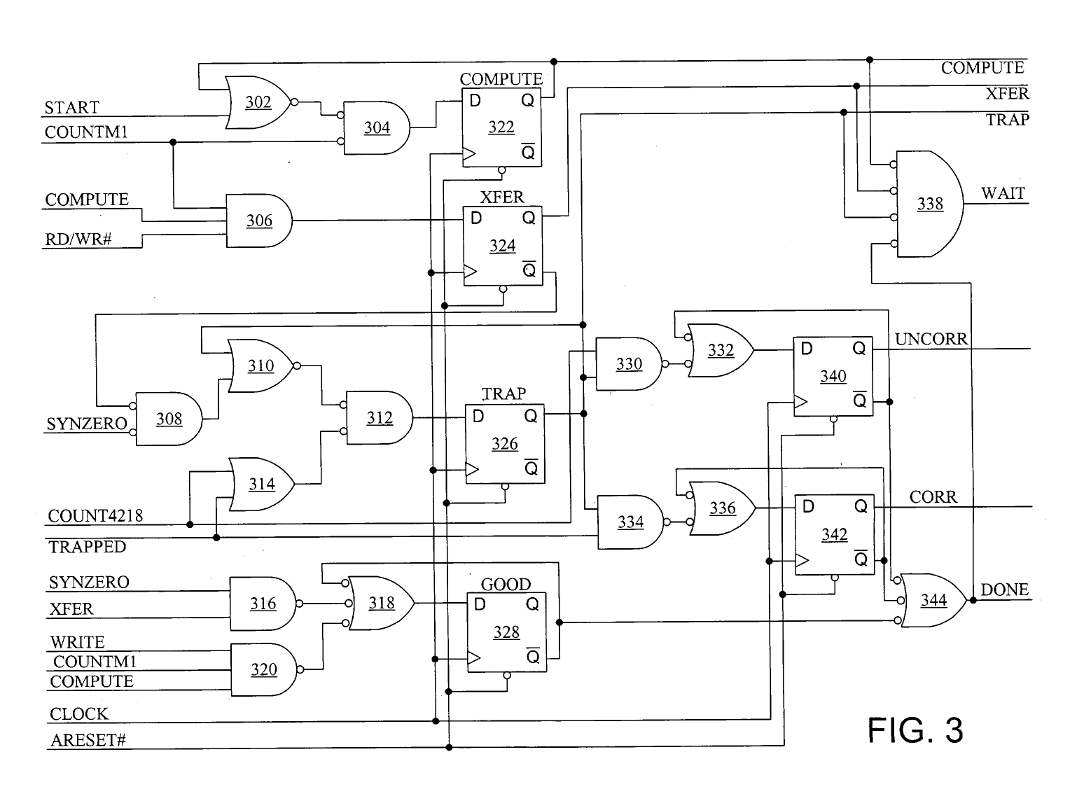

On the other hand, if the ECC syndrome is non-zero, an error has occurred in the data. The syndrome is transferred preferably with all 42 bits in parallel to the error trapper 150. The error trapper 150 is then clocked, and the number of clocks are accumulated in a counter 180. When the error trapper 150 detects a single bit error, a signal TRAPPED (FIG. 3) is made active and the corresponding count held in the counter 180 identifies the bit in error. Since the direction of counting is arbitrary, either an up-counter or a down-counter may be used. Illustratively, if the last bit is bad, only one clock will be needed to locate the error. If the first bit is bad, 4218 clocks (522 bytes×8 bits/byte+42 bits) will be needed to locate the error.

When the error trapper 150 identifies an error, the SRAM bit corresponding to the count in the counter 180 is inverted in the following manner. The 13 bit counter output COUNT is furnished to an address logic circuit 182 that generates a byte address BYTE and a bad bit locator BIT. The value BYTE is furnished to an address decoder (not shown) which transfers the byte containing the bad bit from the page memory 120 to the shift register 130 through the multiplexer/demultiplexer 122 and the multiplexer 134. The value BIT is furnished to a bit inverter circuit 136, which inverts the bit identified by the value BIT in the shift register 130. The byte containing the corrected bit is then transferred back into the page memory 120 through the demultiplexer 132 and the multiplexer/demultiplexer 122, thereby overwriting the incorrect data. The status “corrected error” is recorded in the status register 172 based on signals ECC0 and ECC1, and the application detects this status by reading the status register 172 through the multiplexer 144.

It will be appreciated that a fast internal clock may be used for the internal operations carried out for the “Transfer Main Array Page to Buffer with AutoCorrect” read, including the operations of the error trapper 150. The use of an internal clock that is faster than the external clock significantly reduces the overhead of the ECC read operations.

A “Read Buffer” command causes the user data 210 to be read out from the page memory 120 to the application in the following manner. The user data 210 is written to the shift register 130 byte-by-byte from the page memory 120 through the multiplexer/demultiplexer 122 and the multiplexer 134. For each byte of the user data 210 in the shift register 130, the bits are serially shifted out and furnished to the I/O interface 190 via the demultiplexer 142 and the multiplexer 144.

When the user data 210 contains an error that is uncorrectable by the ECC circuitry 140, the error trapper 150 is unable to identify an error even though the ECC syndrome is non-zero. Accordingly, the status “uncorrectable error” is recorded in the status register 172 based on signals ECC0 and ECC1, and the application detects this status by reading the status register 172 through the multiplexer 144. At this time the application can signal a read failure, or can read the user data 210 with the “Read Buffer” command and ignore the error, or can read out the user data 210 with the “Read Buffer” command as well as the ECC read syndrome using a “Read ECC Syndrome” command and attempt to correct the error external of the serial flash memory 100. A suitable algorithm may be applied to the ECC read syndrome to reveal the locations of two bits in error. This algorithm preferably is performed by an external microprocessor under software or firmware control, although external dedicated hardware may be used if desired.

Although external correction of an error that is uncorrectable by the ECC circuitry 140 can be efficiency performed from the user data 210 and the ECC read syndrome, external correction can be performed from other information. Illustratively, external correction can be performed with the codeword alone where the external system regenerates the read syndrome, or external correction can be performed with the codeword and the read syndrome from the ECC circuitry 140.

The “Read ECC Syndrome” command causes the read syndrome to be read from the syndrome generator 160 to the application in the following manner. Provided that the next ECC command has not yet been issued, the ECC syndrome 220 is preserved at the output of the syndrome generator 160. The ECC syndrome 220 is then copied to the shift register 130 byte-by-byte through the converter 146. For each byte of the ECC read syndrome in the shift register 130, the bits are serially shifted out and furnished to the I/O interface 190 via the demultiplexer 142 and the multiplexer 144.

It will be appreciated that the amount of overhead incurred by the ECC memory read operation varies depending on whether an error occurs and the nature of that error. The ECC system 140 adds a 4218 clock overhead to good pages, and an additional 9 to 4226 clock overhead (1:4218+8 clocks for the read-modify-write) to pages with single bit errors to create valid data. The detection of multiple bit errors requires a 4218 clock overhead to generate the read syndrome, and an additional 4218 clock overhead to determine that the error is uncorrectable. The correction of a multiple bit error adds 49 clocks for clocking out the read syndrome (1+6+42) to the 8436 clocks (4218+4218) needed to detect a multiple bit error. The amount of time required for the overhead may be minimized by clocking the internal circuitry of the flash memory 100, including the ECC system 140, at a faster clock rate than the input and output is clocked.

For applications that perform mostly sequential writes, the user may wish to use the data without performing error correction because of the low probability of memory disturb errors. In this case the application issues a read command called “Transfer Main Array Page to Buffer without AutoCorrect,” which is executed by the serial flash memory 100 in the following manner. The page of data, which includes user data 210, check bits 220, and filler bits 230, is transferred from the flash memory array 110 into the page memory 120 through the array access circuit 112, the multiplexer 134, the shift register 130, the demultiplexer 132, and the multiplexer/demultiplexer 122. In this type of read operation, the 42 check bits 220 and the 6 filler bits 230 are treated as data. The check bits 220 are not clocked from the shift register 130 to the syndrome generator 160.

It will be appreciated that reads and writes without ECC preferably is performed using the entire 528 bytes of a page, although fewer bytes such as the first 522 bytes of the page that correspond to the user data 210 may be used if desired.

If desired, the “Transfer Main Array Page to Buffer with AutoCorrect” command may be combined with the “Read Buffer” command into a single “Read Main Array Page (522 byte) with AutoCorrect” command. Similarly, the “Transfer Main Array Page to Buffer without AutoCorrect” command may be combined with the “Read Buffer” command into a single “Read Main Array Page (528 Byte) without AutoCorrect” command.

While the buffer referred to in foregoing commands is the page memory 120, the term could include a value for distinguishing between two or more buffers in implements having two or more page memories acting as buffers. Alternatively, a volatile memory that is more closely coupled to the flash memory array 110 than is the page memory 120 may be used if desired. Accordingly, the nature of the coupling between the page memory 120 and the flash memory array 110 is not especially pertinent to error correction as described herein.

The ECC system 140 makes the data status available before the data in a read operation in the following manner. Based on outputs from sequencer 170 (the inputs and outputs of the sequencer 170 are not shown in FIG. 1 to avoid unnecessary complexity, but are described below), the ECC system 140 generates signals ECC1 and ECC0, which for the following values have the following meaning: “00” means an error-free read, “01” means a corrected read (corrected single bit error), “10” is undefined, and “11” means an uncorrectable read (a multiple bit error). These signals are stored in the status register 172, which is continuously read by the application through the multiplexer 144 and the I/O interface 190 while the serial flash memory 100 is busy. The application then decides whether to read the user data 210 from the serial flash memory 100 and how to handle it using, for example, one or more of the various commands described above. Alternatively, the serial flash memory 100 automatically provides a suitable output on the first clock after the status read in which the register busy bit shows ready. The suitable output is just the user data 210 if the read is of error-free or error-corrected data, and the user data 210 plus the ECC read syndrome if the read is of uncorrectable data.

Smart refresh is performed by the serial flash memory 100 in the following manner. As previously mentioned, if the error trapper 150 locates an error, a single bit error has occurred and the associated SRAM bit is inverted. Since the corresponding bit of the page in the flash memory array 110 is bad, the corrected data of the page memory 120 is written back to the flash memory array 110 in the background, thereby correcting the bad bit in the flash memory array 110. Depending on the type of flash memory in the array 110, either the entire page is written back or just a part of the page containing the corrected bit, such as, for example, a byte, is written back. If the single bit error is due to memory disturb, it will be corrected by the write back operation. Smart refresh may be performed automatically under control of the serial flash memory itself, or may be instructed by the application when the status “01,” which means a corrected read (corrected single bit error), is reported to and detected by the application.

In a variation of the smart refresh technique, an internal background task may be included in the memory. In one embodiment, the internal background task periodically reads each page of the flash memory array 110 into the page memory 120 using an ECC read, and if a correctable error is detected, makes the correction and writes the corrected data back into the flash memory array 1 10. The internal background task preferably is subject to be enabled and disabled by the application to avoid having the memory unavailable when the application requires it.

Unnecessary write-backs may be caused when the single bit errors are due to uncorrectable problems such as oxide rupture or defective bits in the memory array 110. Since such errors, which are known as “hard” errors, are rare in standard parts during their specified life cycle, the impact of unnecessary write backs on the overall performance of such parts is negligible. However, lower grade parts are likely to have more hard errors, which are uncorrectable and therefore could give rise to a large number of unnecessary refresh write-backs and thereby significantly degrade memory performance. While ECC can still be used in such parts to correct all types of single bit errors, including those from uncorrectable bits, smart refresh should be avoided in such parts to avoid memory performance degradation. Alternatively, various supplemental techniques may be used to suppress write-backs when the single bit errors likely are due to hard errors. An example of a suitable technique is to accumulate the number and/or frequency of corrected single bit errors and to cease smart refresh if the number and/or frequency exceed a particular amount.

Illustrative embodiments of the various elements shown in FIG. 1 are now described in further detail. The serial flash memory 100 includes a flash memory array 110, which preferably is an array of nonvolatile single transistor floating gate memory cells arranged in a virtual ground configuration and erased using the Fowler-Nordheim (“FN”) mechanism and programmed using either the FN mechanism or a hot electron mechanism. It will be appreciated that other types of memory cells such as those having split gate transistors, or other types of charge storage structures, or using other types of charge transport mechanisms, may also be used. Generally speaking, a flash memory is any nonvolatile memory in which a large number of memory cells may be erased simultaneously. Page mode flash memory is a flash memory in which a large number of memory cells known as a page are programmed together. The size of a page typically is hundreds of bytes, and may correspond to a variety of physical arrangements of memory, although the typical arrangement is a row of memory cells in a conventional row:column matrix of cells that is selected by a word line. For purposes of illustration, a page of the flash memory array 110 is considered to be 528 bytes or 4224 bits.

The page memory 120 preferably is a volatile SRAM memory, although other types of fast memory may be used instead. The page memory 120 is preferably of a size so that an entire page of data that is either being programmed into or read from the nonvolatile memory array 110 may be stored therein.

The array access circuit 112 and the multiplexer/demultiplexer 122 direct byte data to and from appropriate positions of the flash memory array 110 and the page memory 120 respectively. Any suitable multiplexers, pass gates, electronic switches, and the like may be used for this purpose. The array access circuit 112 includes additional components for providing read and program access to the memory array 110, including latches, sense amplifiers, and read/write circuits. Such technologies are well known in the art and dependent on the specific design of the nonvolatile memory.

The I/O interface logic circuit 190 interfaces the serial flash memory 100 to the application. Any suitable interface circuit may be used, and a great many suitable interface circuits are well known in the art.

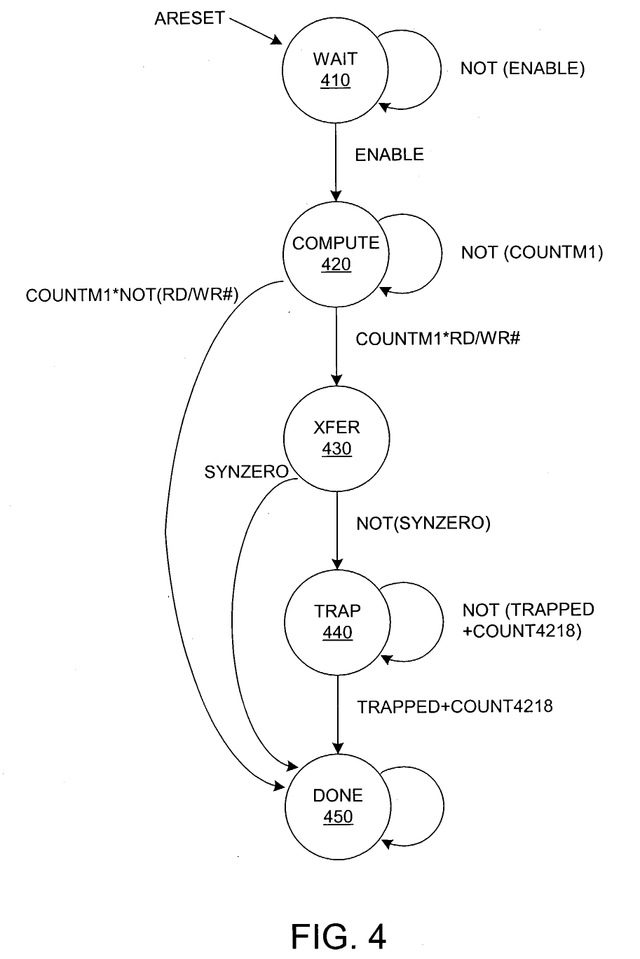

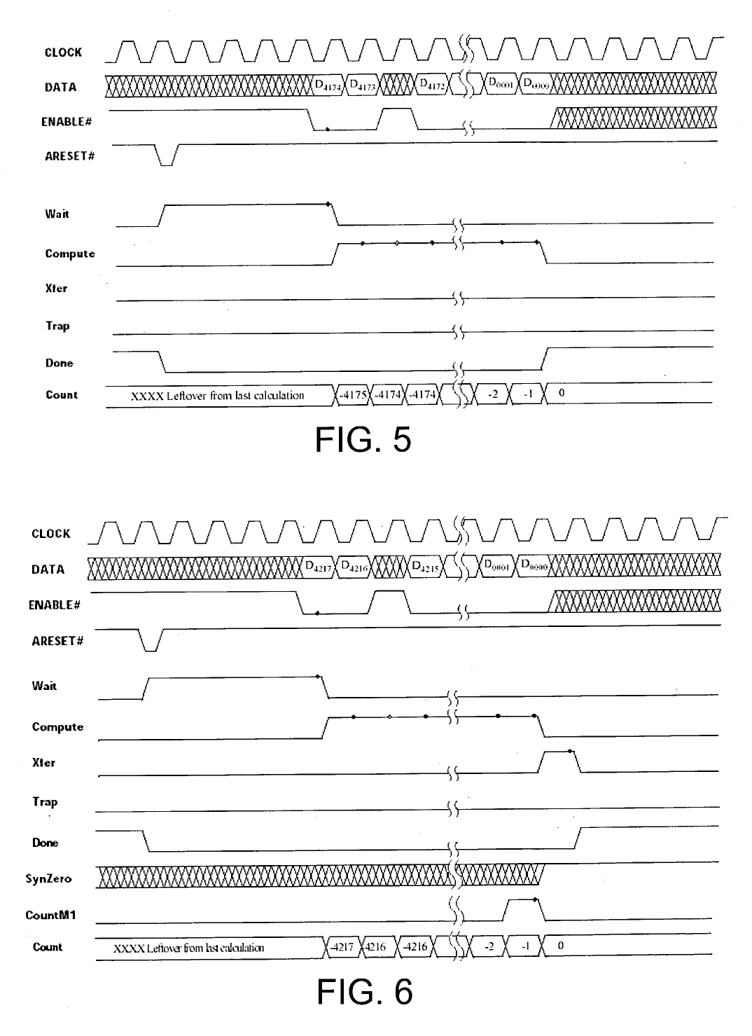

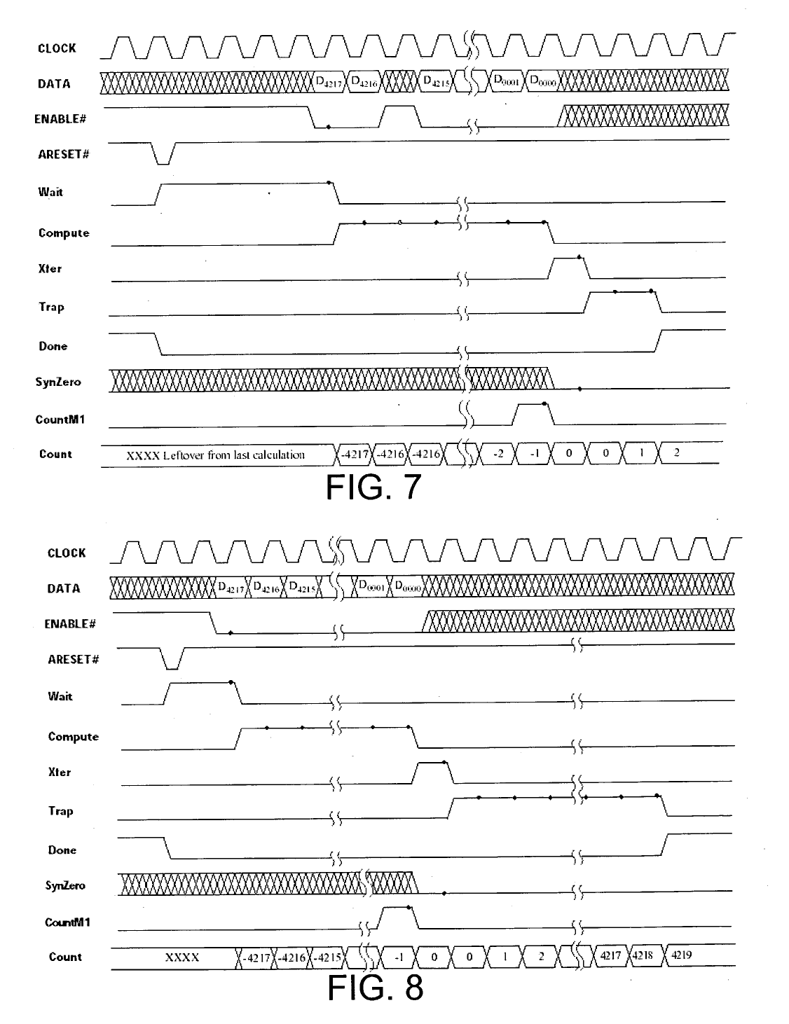

The ECC system 140 includes a sequencer 170 (FIG. 3), which controls the various operations of the ECC system 140 (some control lines are omitted to preserve clarity). An illustrative state diagram for the sequencer 170 is shown in FIG. 4, and various timing diagrams are shown in FIGS. 5-8. The timing diagram of FIG. 5 is characteristic of an ECC write operation, the timing diagram of FIG. 6 is characteristic of an ECC read operation in which no data errors are found, the timing diagram of FIG. 7 is characteristic of an ECC read operation in which a single bit data error is corrected, and the timing diagram of FIG. 8 is characteristic of an ECC read operation with multiple data errors, which are not corrected within the serial flash memory.

As shown in FIG. 3, the sequencer 170 contains a number of flipflops that store the value of various state variables that are calculated from various input signals. For example, signals COUNTM1 and COUNT4218 are from the counter 180, signal SYNZERO is from the zero detector 148, signal TRAPPED is from the error trapper 150, and various other signals are from a memory controller (not shown). Flipflop 322 stores the state value of COMPUTE, flipflop 324 stores the state value of XFER, flipflop 326 stores the state value of TRAP, flipflop 340 stores the state value of UNCORR, and flipflop 342 stores the state value of CORR. In addition, flipflop 328 stores the state value of GOOD, which is an internal state variable. Other output signals are formed by combinations of these state variables. In particular, the output signal DONE is formed by an OR of the signals UNCORR, CORR and GOOD in gate 344; and the output signal WAIT is formed by an AND of the inverted signals COMPUTE, XFER, TRAP and DONE in gate 338. The D-inputs of the various flipflops are provided by various combinatorial sub-circuits of standard logic gates, which operate on the following inputs: ARESET, CLOCK, COUNT4218, COUNTM1, COMPUTE, RD/WR#, START, SYNZERO, TRAPPED, WRITE, and XFER. The operation of the circuit of FIG. 3 will be apparent from the following description of the state diagram in FIG. 4 and the timing diagrams in FIGS. 5-8.

The ECC system 140 reports data status before data transfer using signals ECC1 and ECC0. Signal ECC0 is an OR of the state value of UNCORR stored in the flipflop 340 and the state value of CORR stored in the flipflop 342. Signal ECC1 is the state value of UNCORR stored in the flipflop 340.

The sequencer 170 operates in the manner shown in FIG. 4. The sequencer 170 enters a wait state 410 after being reset by assertion of the signal ARESET, and remains in the wait state 410 for so long as ENABLE remains not asserted. The signal ENABLE is used to generate the sequencer 170 input signal START in accordance with the expression ENABLE NAND WAIT. When ENABLE is asserted, the sequencer 170 enters into a compute state 420 in which it computes a syndrome for the user bit-serial data for so long as COUNTM1 is not asserted. When COUNTM1 is asserted and RD/WR# is not asserted, an event that occurs during a memory write operation when all of the user data 210 has been clocked through the syndrome generator 160, the sequencer 170 enters a done state 450. When both COUNTM1 and RD/WR# are asserted, an event that occurs during a memory read operation when all of the user data 210 and the ECC syndrome 220 (not including the filler bits 230) have been clocked through the syndrome generator 160, the sequencer 170 enters a transfer (“xfer”) state 430 in which the read syndrome is transferred to the error trapper 150. However, if SYNZERO is asserted indicating that no error has occurred, the sequencer 170 enters into the done state 450. If SYNZERO is not asserted indicating that the data has one or more errors, the sequencer 170 enters into the trap state 440 and remains in the trap state 440 until a single bit error is trapped or the error trapper 150 has been clocked through all 4218 cycles. The sequencer 170 then enters the done state 450.

The timing diagram of FIG. 5 is characteristic of an ECC write operation. The sequencer 170 is reset by assertion of ARESET# and begins to clock in DATA for the flash memory array 110 after a short period as indicated by assertion of WAIT. As the data is serially clocked through the ECC system 140, the syndrome is being computed as indicated by assertion of COMPUTE, and the count is decreasing from 4175 to 0, which is the number of bits in the user data 210. The syndrome is completed just after the last bit of the user data 210 is clocked, transferred to the converter 146 with the filler bits 230 added, and clocked (not shown) from the converter 146 in 6 one-byte transfers.

The timing diagram of FIG. 6 is characteristic of an ECC read operation in which no data errors are found. The sequencer 170 is reset by assertion of ARESET# and begins to clock in DATA from the flash memory array 110 after a short period as indicated by assertion of WAIT. As the data is serially clocked through the ECC system 140, the read syndrome is being computed as indicated by assertion of COMPUTE, and the count is decreasing from 4217 to 0, which is the number of bits in the user data 210 and the ECC syndrome 220. Just before the last bit of data is clocked through the ECC system 140, COUNTM1 is asserted to indicate this. Next, XFER is asserted to transfer the read syndrome to the error trapper 150, and SYNZERO is asserted to indicate that the data has no errors. Since the data has no errors, it is then clocked (not shown) from the page memory 120 to the I/O interface 190.

The timing diagram of FIG. 7 is characteristic of an ECC read operation in which a single bit data error is corrected. The sequencer 170 is reset by assertion of ARESET# and begins to clock in DATA from the flash memory array 110 after a short period as indicated by assertion of WAIT. As the data is serially clocked through the ECC system 140, the read syndrome is being computed as indicated by assertion of COMPUTE, and the count is decreasing from 4217 to 0, which is the number of bits in the user data 210 and the ECC syndrome 220. Just before the last bit of data is clocked through the ECC system 140, COUNTM1 is asserted to indicate this. Next, XFER is asserted to transfer the read syndrome to the error trapper 150, and SYNZERO is not asserted to indicate that the data has errors. TRAP becomes asserted, whereby the error trapper 150 is clocked while COUNT keeps track of the number of cycles, which indicates the position of the error. In the example of FIG. 7, the error is found after just three clocks at bit position 2, and indicated by assertion of the signal TRAPPED (not shown) to the sequencer 170, de-assertion of TRAP, and the value 2 in COUNT. Bit position 2 in the page memory 120 is inverted to correct the single bit error through a read-modify-write operation, and the corrected user data 120 is clocked (not shown) from the page memory 120 to the I/O interface 190.

The timing diagram of FIG. 8 is characteristic of an ECC read operation with multiple data errors, which are not corrected within the serial flash memory. The sequencer 170 is reset by assertion of ARESET# and begins to clock in DATA from the flash memory array 110 after a short period as indicated by assertion of WAIT. As the data is serially clocked through the ECC system 140, the read syndrome is being computed as indicated by assertion of COMPUTE, and the count is decreasing from 4217 to 0, which is the number of bits in the user data 210 and the ECC syndrome 220. Just before the last bit of data is clocked through the ECC system 140, COUNTM1 is asserted to indicate this. Next, XFER is asserted to transfer the read syndrome to the error trapper 150, and SYNZERO is not asserted to indicate that the data has errors. TRAP becomes asserted, whereby the error trapper 150 is clocked while COUNT keeps track of the number of cycles, which indicates the position of the error. Because the error is not a single bit error, error trapper 150 is clocked through all 4218 cycles without asserting the signal TRAPPED (not shown) to the sequencer 170. Next, the entire page of uncorrected user data 210, the ECC syndrome 220, and the filler bits 230 are clocked (not shown) from the page memory 120 to the I/O interface 190. If desired, the filler bits 230 need not be clocked out.

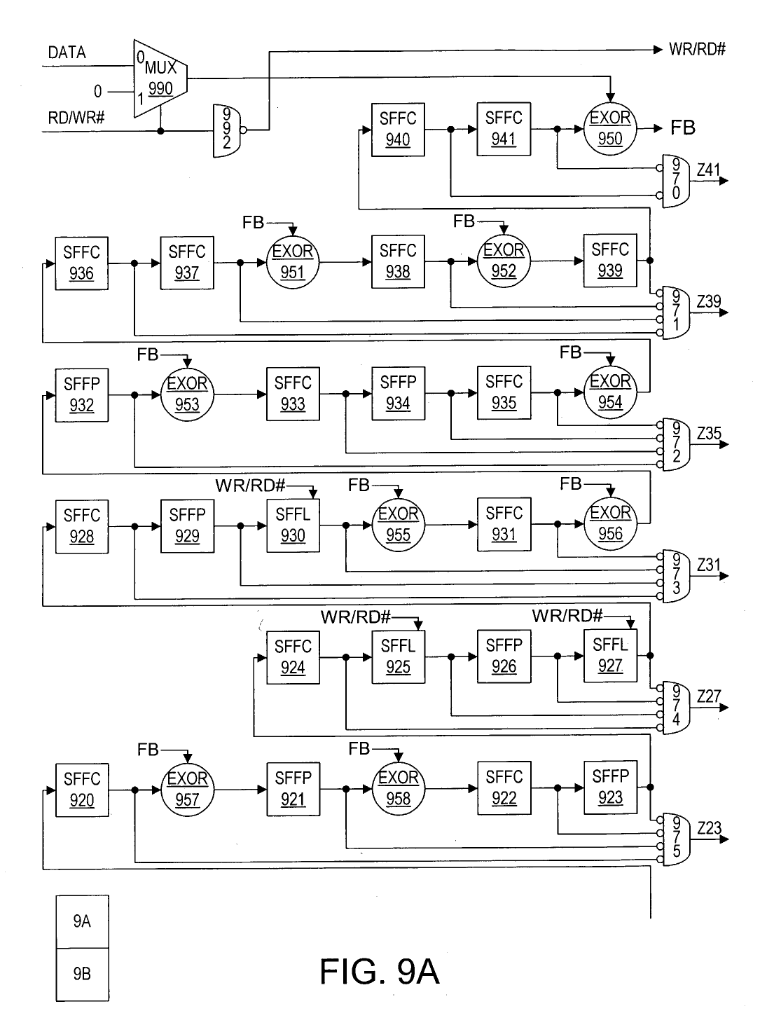

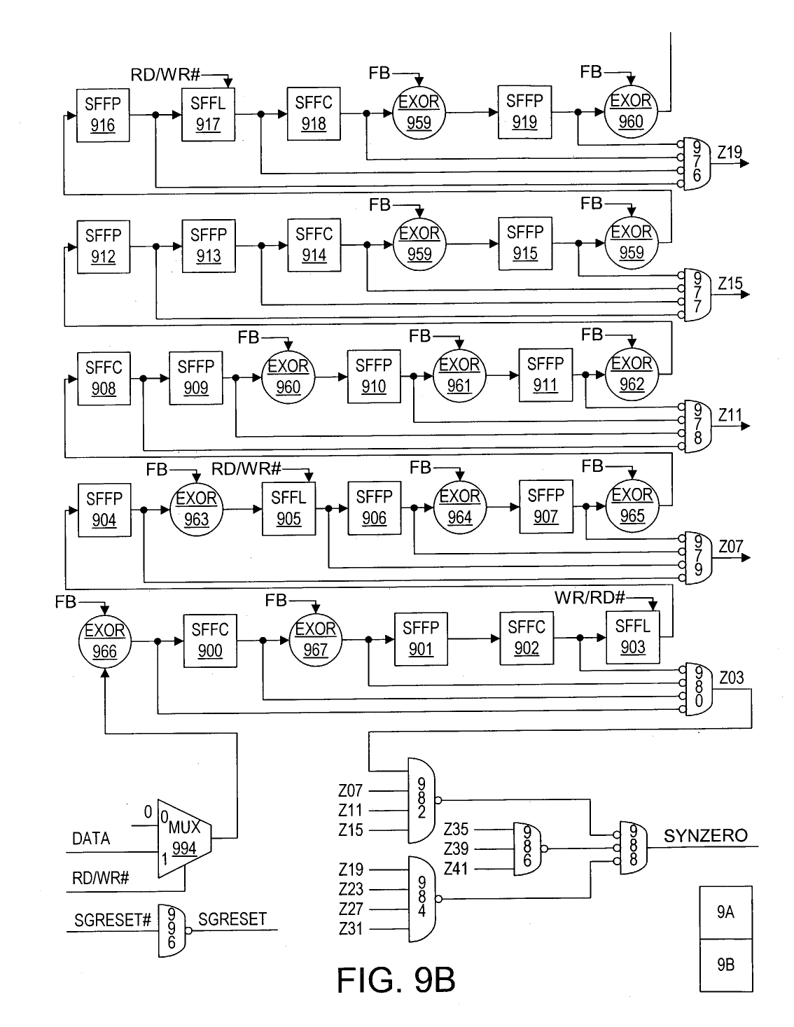

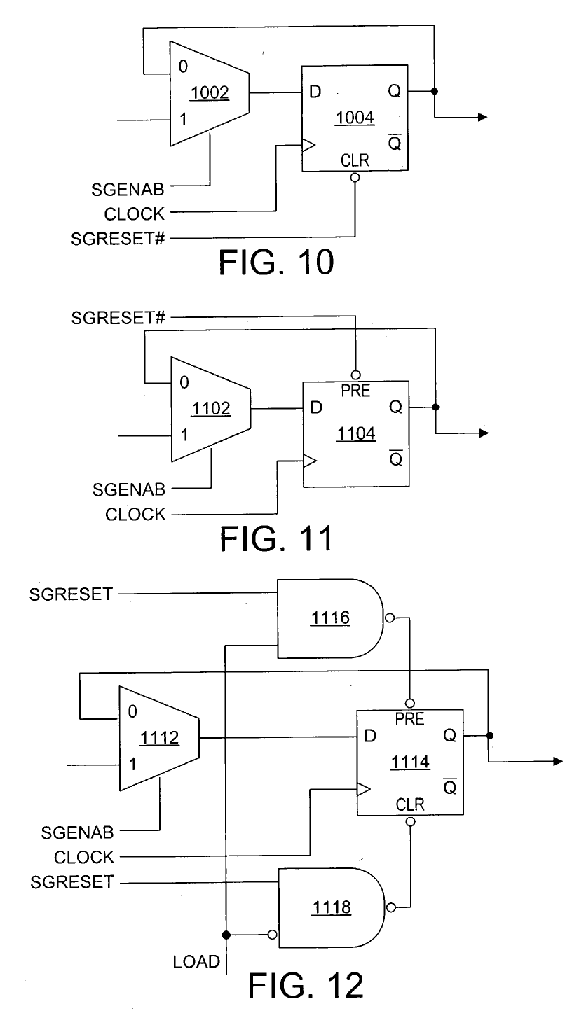

An illustrative detailed embodiment of the syndrome generator 160 is shown in FIG. 9A and in FIG. 9B. It is constructed using components SFFC, SFFP, and SFFL, shown in greater detail in FIG. 10, FIG. 11, and FIG. 12 respectively. The circuits SFFC, SFFP and SFFL are essentially gated flip-flops and function the same except during reset when the signal SGRESET# is asserted. When SGRESET# is asserted, or low: (a) the SFFC flip-flop 1004 is forced to the reset or “0” state; (b) the SFFP flip-flop 1104 is forced to the set or “1” state; and (c) the SFFL flip-flop 1114 is loaded with the data value present on the load input LOAD. If the load input LOAD of a SFFL is “1” when SGRESET# is asserted (low), then the SFFL flip-flop 1114 is forced to a “1” state. If the load input LOAD of a SFFL is “0” when the SGRESET# is asserted (low), then the SFFL flip-flop 1114 is forced to a “0” state. SFFC, SFFP, and SFFL all function in the same way when SGRESET# is not asserted (high). The signal coming into each function block from the left is the input, and the signal leaving each function block to the right is the output. When the signal SGENAB is not asserted, multiplexers 1002, 1102 and 1112 re-circulate the output of the SFFC, SFFP, and SFFL flip-flops 1004, 1104 and 1114 respectively back to their “D” inputs, so that the when the CLOCK signal is transitioned the state of the flip-flops 1004, 1104 and 1114 does not change. When the signal SGENAB is asserted, the multiplexers 1002, 1102 and 1112 direct the inputs of the SFFC, SFFP, and SFFL circuits to the flip-flops 1004, 1104 and 1114 respectively, so that when the CLOCK signal is transitioned, the flip-flops 1004, 1104 and 1114 latch in the data present on the inputs of the SFFC, SFFP, and SFFL circuits. Thus, SFFC, SFFP, and SFFL act as gated flip-flops, latching the data on their inputs on CLOCK signal transitions that occur when the enable signal SGENAB is asserted and outputting the last latched data on their outputs.

The syndrome generator 160 is a shift register interspersed with exclusive OR logic gates. The shift register is constructed from the gated flip-flops SFFC, SFFP, and SFFL, so that a shift will occur whenever the CLOCK signal transitions when SGENAB is asserted. A shift register and exclusive OR logic gate circuit such as this performs polynomial division. The polynomial represented by the bits presented in sequence on the DATA signal is divided by the polynomial represented by the placement of the exclusive OR logic gates. The gated flip-flops store the remainder of the results of polynomial division. Gated flip-flop SFFC 941 stores the most significant bit of the remainder, gated flip-flop SFFC 900 stores the least significant bit of the remainder, with the other bits of the remainder stored in order in the gated flip-flops 901-940 between these two. The remainder of the polynomial division is examined by a series of AND logic gates 970 through 980 and 982, 984, 986 and 988 to determine if all the bits in the remainder are zero, and if so the SYNZERO signal is asserted.

The polynomial that is formed by the placement of the exclusive OR gates 950-967, and that divides the polynomial represented by the bits presented in sequence on the DATA signal, is the generator polynomial in Expression (1). Each “1” coefficient in the polynomial is represented by the presence of an exclusive OR gate. Therefore, the x⁰ term in the generator polynomial is represented by the exclusive OR gate EXOR 966, the x¹ term is represented by the exclusive OR gate EXOR 967, and so forth. The lack of the x² term in the generator polynomial is represented by lack of an exclusive OR gate between SFFP 901 and SFFC 902. The remaining terms of the generator polynomial are implemented in exclusive OR gates in a similar fashion, ending with the x⁴² term in the generator polynomial being represented by EXOR 950.

Advantageously, the syndrome generator 160 calculates both the write syndrome or check bits 220 during write operations and the read syndrome during read operations. During write operations when encoding cyclic codes (such as BCH codes), the polynomial formed by the incoming sequential data bits is multiplied by x^{m}, where m is the order of the generator polynomial, before dividing it by the generator polynomial; see Chapter 4 of the aforementioned work by Lin and Costello, Jr. This performs the function of shifting the data bits m places higher in the polynomial and makes room for the write syndrome to be appended. Because the syndrome generator 160 implements a generator polynomial of order 42, the polynomial represented by the incoming data is premultiplied by x⁴² before the polynomial division is performed. This is accomplished by the multiplexer MUX 990, which steers the input data bits to the x⁴² term of the shift register when the RDIWR# signal is not asserted (indicating that a write operation is occurring). When computing the read syndrome, this pre-multiplication is not required. This is accomplished by the multiplexer MUX 994 steering the input data bits to the x⁰ term of the shift register when the RD/WR# signal is asserted (indicating that a read operation is occurring). It should be noted that it is possible to use a write syndrome generator 160, with its pre-multiplication of x^{m}, during reading and still construct a functioning correction subsystem. However, before any algorithmic processing can occur, such as is required for multiple bit correction, the resulting syndrome must be converted into a conventional read syndrome. This conversion would require considerable processing. Using a read syndrome generator 160 without the pre-multiplication of x^{m} advantageously avoids this additional processing.

The syndrome generator 160 is initialized to a known state before data is processed through it, so that the resulting syndrome is uniquely determined by the specific data pattern. Although initialization can be accomplished by simply clearing (setting to “0”) the flip-flops of the syndrome generator 160, this technique suffers from the disadvantage that it makes the ECC codeword containing all zeros valid. If a malfunction were to occur in the logic transmitting data to or from the flash memory in such a way as to clear all bits stored to “0,” an ECC system using a syndrome generator 160 that initialized to all Os would detect a valid ECC codeword and the error would go unreported. Preferably, the syndrome generator 160 is initialized to a non-zero pattern before processing data, to avoid this problem. This makes the “all bits zero” codeword not a valid ECC codeword, and enables detection of the type of malfunction that clears the bits.

Initializing the syndrome generator 160 to a non-zero pattern could be accomplished by initializing the flip-flops to all zeros, and then sending the syndrome generator 160 a fixed, non-zero data pattern prior to sending it the actual data. Alternatively, the syndrome generator 160 could be initialized by forcing the flip-flops to the same state the syndrome generator 160 would have after processing the initialization pattern. Because the write syndrome generator 160 function premultiplies by x^{m} while computing the polynomial division, and the read syndrome generator 160 function does not perform the pre-multiplication, the value in the syndrome generator 160 in these different circumstances must be different after processing the initialization pattern. Therefore, if the read and write syndrome generator functions are to be initialized by presetting them rather than by sending them an initialization pattern, the two syndrome generator functions must be preset to different values.

The syndrome generator 160 in this invention performs both write and read syndrome generation functions. The syndrome generator 160 is preloaded to one of two different values when SGRESET# is asserted (low), depending on whether a read or write is being performed, as indicated by the state of the RD/WR# signal. To reduce the amount of logic circuitry required to implement the syndrome generator 160, the write and read preload values were chosen so they only differ by a limited number of bits. A computer was used to choose initialization patterns at random, and then to calculate resulting read syndromes and write syndromes using the generator polynomial listed in equation (1). Each resulting pair of read and write syndromes were compared to determine the number of bits different between the two. The pair of syndromes that differed in the fewest number of bits was remembered. After many hours of processing, a pair of syndromes that differed by only six bits was discovered and these are used as preload values in this embodiment. These preload values are:

Write=0 1 0 0 0 0 0 1 0 1 0 1 1 0 1 1 1 0 1 0 1 0 1 0 0 1 1 0 1 1 1 1 1 0 1 1 0 1 1 0 1 0

Read=0 1 0 0 0 0 0 1 0 1 0 0 1 0 0 1 0 0 1 0 1 0 1 0 1 1 1 0 1 1 1 1 1 0 1 1 1 1 0 0 1 0

In hexadecimal, the write syndrome preload value is 1056EA9BEDAh and the read syndrome preload value is 10524ABBEF2h.

The syndrome generator 160 is initialized to the correct preload value when SGRESET# is asserted (low), depending of whether a read is being performed (RD/WR# asserted or “1”) or whether a write is being performed (RDIWR# not asserted or “0”). The preload value is determined by which component is used to implement each bit of the syndrome generator 160. For the SFFC circuit of FIG. 10, the bit of the syndrome generator 160 that it implements is always initialized to “0” when SGRESET# is asserted. For the SFFP circuit of FIG. 11, the bit of the syndrome generator 160 that it implements is always initialized to “1” when SGRESET# is asserted. For the SFFL circuit of FIG. 12, the bit of the syndrome generator 160 that it implements is initialized to value present on its load input LOAD. If the load input of the SFFL circuit is connected to the RD/WR# signal, then the load input is “1” on reads and “0” on writes, and that syndrome bit initializes to “1” on reads and “0” on writes. Conversely, if the load input of the SFFL circuit is connected to the WR/RD# signal, then the load input is “0” on reads and “1” on writes, and that syndrome bit will initialized to “0” on reads and “1” on writes. As shown in FIG. 9B, for example, the least significant bit of the syndrome generator 160 is implemented with SFFC 900, so it is initialized to “0” for both read and write syndrome generation functions. The next most significant bit of the syndrome generator 160 is implemented with SFFP 901, so it is initialized to “1” for both read and write syndrome generation functions. The next most significant bit of the syndrome generator 160 is implemented with SFFC 902, so it is initialized to “0” for both read and write syndrome generation functions. The next most significant bit of the syndrome generator 160 is implemented with SFFL 903 with the load input connected to WR/RD#. This bit is therefore initialized to “0” during reads and to “1” during writes. Examining the write and read preloads listed above will show that this is the desired function.

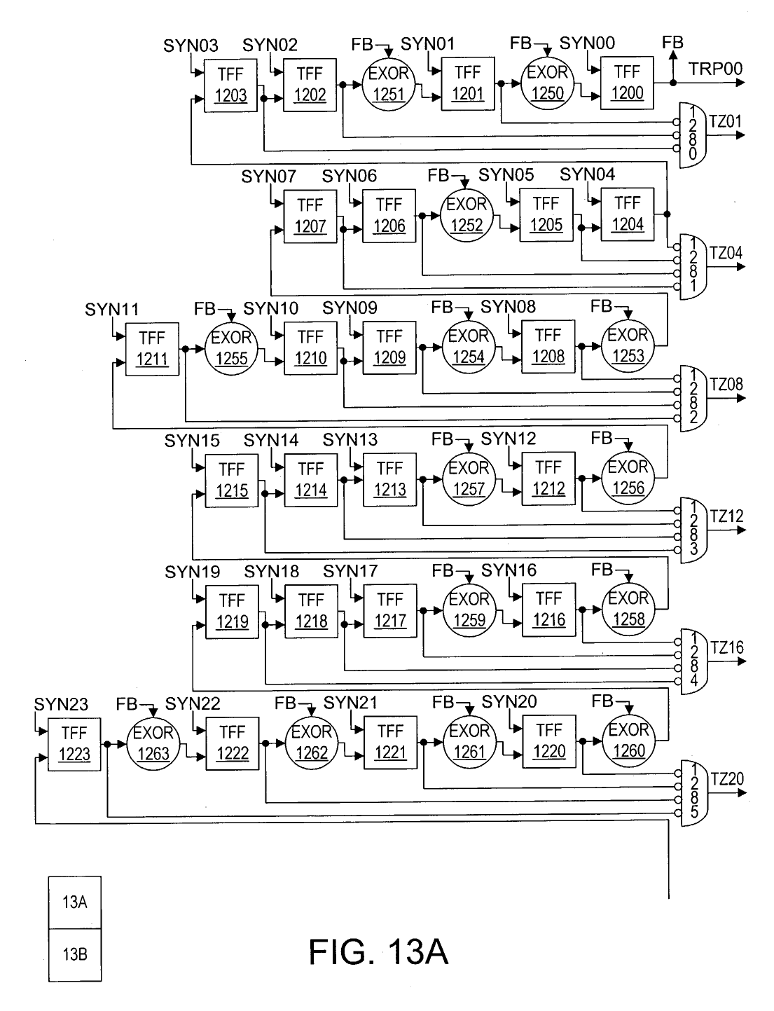

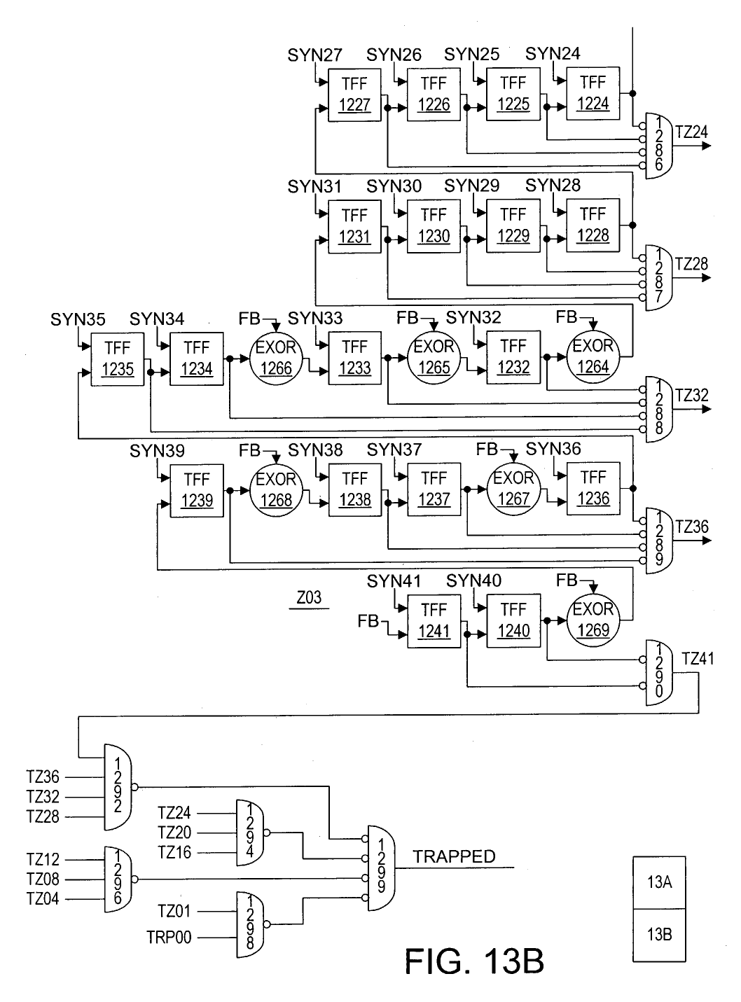

An illustrative embodiment of the error trapper 150 is shown in FIG. 13A and in FIG. 13B, and the TFF component thereof is shown in greater detail in FIG. 14. The TFF component shown in FIG. 14 has a flip-flop that is loaded from one of two inputs whenever the CLOCK signal transitions. Which input to TFF that will load the flip-flop is determined by the TRAP/LOAD# signal. The TFF components are connected in the error trapper so that when the TRAP/LOAD# signal is not asserted (low) the error trapper flip-flops are loaded with the data present on the signals SYN00, SYN01, . . . , SYN 41, that data being the contents of the syndrome generator 160 on every transition of the CLOCK signal. When the TRAP/LOAD# signal indicates TRAP (TRAP/LOAD# is asserted or high), on each transition of the CLOCK signal, each flip-flop is loaded with a value computed from the outputs of other bits of the error trapper. During this time, the error trapping calculation is performed.

The error trapper 150 implements the same generator polynomial that is used in the syndrome generator 160, i.e. the polynomial set forth in expression (1). As with the syndrome generator 160, the coefficients of the polynomial implemented in the error trapper are determined by the presence or absence of exclusive OR gates. Thus, TFF 1200 contains the least significant bit of the error trapper 150 and EXOR 1250 corresponds to the x⁰ term of the generator polynomial. Likewise, TFF 1201 contains the next most significant bit and EXOR 1251 corresponds to the x¹ term. The absence of an exclusive OR gate between TFF 1202 and TFF 1203 indicates there is no x² term in the generator polynomial.

The error trapper 150 operates in a similar fashion to the syndrome generator 160, except that the shift register operates in the reverse direction. The syndrome generator 160 shifts in the direction from least significant bit to most significant bit, as required to perform polynomial division. The error trapper 150 shifts in the direction of from most significant bit to least significant bit. Thus the error trapper is the syndrome generator 160 running in reverse. While instructed to TRAP (TRAP/LOAD# is asserted or “1”), for each transition of the CLOCK signal, the error trapper calculates the read syndrome that came before the read syndrome it currently contains.

The logic gates 1280 through 1290 and 1292, 1294, 1296, 1298 and 1299 compare the contents of the error trapper with the data pattern of all ‘0’s except for the least significant bit, which is “1.” A read syndrome of this pattern corresponds to a single bit error in the least significant bit, as explained in the aforementioned work of Lin and Costello, Jr. If this pattern is detected, the error trapper 150 indicates it by asserting the TRAPPED signal. By cycling the error trapper once (one transition of the CLOCK signal) in TRAP mode (TRAP/LOAD# is asserted or ‘1’), the error trapper 150 calculates the read syndrome that came before the current value. If that value is the “all zeros and single one” pattern, then there was a single bit error in the second bit. This process can be repeated to determine if there was an error in the third bit, and so on. By counting the number of cycles until the TRAPPED signal is asserted, the location of a single bit error can be determined.

The converter 146 converts the 42 bit parallel syndrome into six sequential bytes, five of which contain 8 of the check bits 220, and one of which contains 2 of the check bits 220 and the 6 filler bits 230. Any circuit or device for performing this function may be used, including such well known devices as arrays of gates and load inverters.

The counter 180 counts clock cycles and provides the count as a 13 bit binary value, and the address logic 182 uses 10 of the bits for the BYTE value and the remaining 3 bits for the BIT value. Any circuit or device for performing these function may be used, including such well known devices as AND gates, D registers, and multiplexers.

The bit inverter 136 detects the binary value of the bit identified by the value BIT and flips its value in the shift register 130. Any circuit or device for performing these function may be used, including well known decoders using NAND gates or inverter gates.

The description of the invention and its applications as set forth herein is illustrative and is not intended to limit the scope of the invention. Variations and modifications of the embodiments disclosed herein are possible, and practical alternatives to and equivalents of the various elements of the embodiments will be apparent to those of ordinary skill in the art from a reading of this detailed description. For example, the various data paths through the serial flash memory 100, and interfaces to and from the serial flash memory 100, are illustrative, and other combinations of I/Os, multiplexers, demultiplexers, registers, volatile memories, latches, sense amplifiers, read/write circuits, and so forth may be used if desired to control the flow and internal storage of data. The various page sizes and path sizes are illustrative, and may be varied as desired. In some embodiments, the serial I/Os may be replaced by a parallel I/O that transfers two or more bits at a time. These and other variations and modifications of the embodiments disclosed herein may be made without departing from the scope and spirit of the invention.

1. An integrated circuit operable in an ECC memory write mode and an ECC memory read mode, comprising:
a data path disposed in the integrated circuit;
a flash memory array disposed in the integrated circuit and coupled to the data path;
an ECC circuit disposed in the integrated circuit and coupled to the data path for:
creating from first data a single large write codeword using a bit-correcting ECC code during the ECC write mode; and
generating a read syndrome from a read codeword using the bit-correcting ECC code during the FCC read mode; and
a data interface coupled to the data path for furnishing the first data thereto during the ECC write mode.

2. The integrated circuit of claim 1 wherein the ECC circuit comprises a sequential FCC detection engine having a bit-serial coupling to the data path.

3. The integrated circuit of claim 2 wherein the ECC detection engine comprises:
a single syndrome generator coupled to the data path and configurable during the write mode for creating the write codeword from the first data, and configurable during the read mode for generating the read syndrome from the read codeword; and
an error trapper coupled to the syndrome generator.

4. The integrated circuit of claim 3 wherein the syndrome generator uses a BCH ECC code.

5. The integrated circuit of claim 2 wherein the ECC detection engine comprises:
a write syndrome generator coupled to the data path for creating the write codeword from the first data during the write mode;
a read syndrome generator coupled to the data path for generating the read syndrome from the read codeword during the read mode; and
an error trapper coupled to the read syndrome generator.

6. The integrated circuit of claim 1 wherein the ECC circuit comprises a sequential ECC detection and correction engine having a bit-serial coupling to the data path.

7. The integrated circuit of claim 6 wherein the ECC correction engine comprises:
a single syndrome generator coupled to the data path and configurable during the write mode for creating the write codeword from the first data, and configurable during the read mode for generating the read syndrome from the read codeword;
an error trapper coupled to the syndrome generator;
a counter;
a sequencer coupled to the error trapper and the counter, and further coupled to the data path for furnishing an error status indicator;
address logic coupled to the counter; and
a bit inverter coupled to the address logic and to the data path.

8. The integrated circuit of claim 7 wherein the syndrome generator uses a BCH ECC code.

9. The integrated circuit of claim 1 wherein the flash memory comprises a plurality of memory pages of a predetermined page size, the write and read codewords being of a size equal or substantially equal to the page size, and the first data being of a size less than the page size.

10. The integrated circuit of claim 1 wherein the data path is further configurable in an non-ECC write mode and a non-ECC read mode.

11. The integrated circuit of claim 10 wherein:
the flash memory comprises a plurality of memory pages of a predetermined page size, the write and read codewords being of a size equal or substantially equal to the page size and the first data being of a size less than the page size; and
the data interface circuit further is coupled to the data path for furnishing thereto second data of a size equal or substantially equal to the page size during the non-ECC write mode.

12. The integrated circuit of claim 10 wherein:
the flash memory comprises a plurality of memory pages of a predetermined page size, the write and read codeword being of a size equal or substantially equal to the page size and the first data being of a size less than the page size; and
the data interface circuit further is coupled to the data path for furnishing thereto second data of a size equal to the size of the first data during the non-ECC write mode.

13. The integrated circuit of claim 1 wherein the data interface comprises a bit-serial input/output circuit.

14. The integrated circuit of claim 1 wherein the data interface comprises a parallel-to-serial input circuit and a serial-to-parallel output circuit.

15. The integrated circuit of claim 1 further comprising a page memory disposed in the integrated circuit and coupled to the data path.

16. An integrated circuit operable in an ECC memory write mode and an ECC memory read mode, comprising:
a data path disposed in the integrated circuit;
a flash memory array disposed in the integrated circuit and coupled to the data path;
an ECC circuit disposed in the integrated circuit and coupled to the data path for:
creating from first data a single large write codeword during the ECC write mode; and
generating a read syndrome from a read codeword during the ECC read mode; and
a bit-serial data interface coupled to the data path for furnishing the first data thereto during the ECC write mode.

17. The integrated circuit of claim 16 wherein the ECC circuit comprises a sequential ECC detection engine using a bit-correcting ECC code and having a bit-serial coupling to the data path.

18. The integrated circuit of claim 16 wherein the ECC circuit comprises a sequential ECC detection and correction engine using a bit-correcting ECC code and having a bit-serial coupling to the data path.

19. The integrated circuit of claim 18 wherein the bit-correcting ECC code is a BCH ECC code.

20. A method of correcting erroneous data in an integrated circuit having a flash memory array, comprising:
receiving binary data;
creating a single large codeword from the data with a bit-correcting ECC code;
programming the codeword into the flash memory array;
reading the codeword from the flash memory array;
generating a read syndrome from the codeword read in the reading step;
evaluating the read syndrome to determine a condition of the codeword read in the reading step; and
when the codeword condition is an error condition, attempting to correct the error condition internally in the integrated circuit as determined by the read syndrome.

21. The method of claim 20 wherein the attempting step is at least in part performed in a hardware error trapper disposed in the integrated circuit.

22. The method of claim 20 wherein the error condition is a small error condition, further comprising:
successfully completing the attempting step to obtain a corrected codeword internally in the integrated circuit; and
furnishing a recovered form of the data from the corrected codeword as an output of the integrated circuit.

23. The method of claim 20 wherein the error condition is a large error condition, further comprising:
unsuccessfully completing the attempting step; and
furnishing information suitable for enabling off-chip recovery of the data from the codeword read in the reading step, as an output of the integrated circuit.

24. The method of claim 23 wherein the information furnished as the output of the integrated circuit comprises the codeword read in the reading step.

25. The method of claim 23 wherein the information furnished as the output of the integrated circuit comprises the codeword read in the reading step and the read syndrome.

26. The method of claim 23 wherein the information furnished as the output of the integrated circuit comprises a data section of the codeword read in the reading step and the read syndrome.

27. The method of claim 20 wherein:
the flash memory array comprises a plurality of memory pages of a predetermined page size, the codewords programmed in the programming step and read in the reading step being of a size equal or substantially equal to the page size and the data being of a size less than the page size; and
the error condition is internally correctable in the integrated circuit for a one bit error, and is externally correctable for at least a two bit error.

28. The method of claim 20 wherein the data receiving step comprises receiving the data in a bit-serial manner.

29. A method of storing user data in and retrieving user data from a nonvolatile page-mode memory array disposed in an integrated circuit and having a plurality of pages of a common size, comprising:
determining within the integrated circuit a single ECC codeword from successive bits of data using a bit-correcting ECC code, the ECC codeword being of a size equal or substantially equal to the page size and comprising the data and a write syndrome;
storing the ECC codeword in a page of the nonvolatile memory array by page mode programming;
reading the ECC codeword from the page of the flash memory array;
calculating within the integrated circuit a read syndrome from the ECC codeword read in the reading step; and
performing within the integrated circuit an error trapping operation using the read syndrome.

30. The method of claim 29:
wherein the error trapping operation performing step comprises generating within the integrated circuit an error location;
further comprising correcting within the integrated circuit an error at the error location in the ECC codeword read in the reading step.

31. The method of claim 29 wherein:
the reading step comprises reading the ECC codeword from the page of the flash memory array to a volatile memory in the integrated circuit having substantially a page of storage capacity; and
the calculating step comprises calculating the read syndrome from the ECC codeword in the volatile memory.

32. The method of claim 29 further comprising acquiring the data through a bit-serial interface.

33. A method of storing user data in and retrieving user data from a flash memory array that is part of a serial flash integrated circuit, comprising:
calculating a write syndrome in the serial flash integrated circuit from successive bits of the user data with a bit-correcting ECC code;
storing the user data and the ECC write syndrome in a page of the flash memory array as an ECC codeword;
reading the ECC codeword from the page of the flash memory array to a volatile memory having essentially a page of storage capacity, the volatile memory being part of the serial flash integrated circuit;
calculating a read syndrome from the ECC codeword read in the reading step;
detecting a one bit error and location information therefor from the read syndrome; and
correcting the one bit error in the volatile memory by use of the location information.

34. The method of claim 33 wherein:
the serial flash integrated circuit comprises a syndrome generator; and
the ECC syndrome calculating step and the read syndrome calculating step are performed in the syndrome generator.

35. A method of correcting erroneous data in an integrated circuit having a flash memory array, comprising:
receiving binary data in bit-serial form;
creating a single large codeword from the data;
programming the codeword into the flash memory array;
reading the codeword from the flash memory array;
generating a read syndrome from the codeword read in the reading step;
evaluating the read syndrome to determine a condition of the codeword; and
when the codeword condition is an error condition, attempting to correct the error condition internally in the integrated circuit as determined by the read syndrome.

36. The method of claim 35 wherein the attempting step is at least in part performed in a hardware error trapper disposed in the integrated circuit.

37. The method of claim 35 wherein the error condition is a small error condition, further comprising:
successfully completing the attempting step to obtain a corrected codeword internally in the integrated circuit; and
furnishing a recovered form of the data from the corrected codeword as an output of the integrated circuit.

38. The method of claim 35 wherein the error condition is a large error condition, further comprising:
unsuccessfully completing the attempting step; and
furnishing information suitable for enabling off-chip recovery of the data from the codeword read in the reading step, as an output of the integrated circuit.

39. The method of claim 38 wherein the information furnished as the output of the integrated circuit comprises the codeword read in the reading step.

40. The method of claim 38 wherein the information furnished as the output of the integrated circuit comprises the codeword read in the reading step and the read syndrome.

41. The method of claim 38 wherein the information furnished as the output of the integrated circuit comprises a data section of the codeword read in the reading step and the read syndrome.

42. The method of claim 35 wherein:
the flash memory array comprises a plurality of memory pages of a predetermined page size, the codewords programmed in the programming step and read in the reading step being of a size equal or substantially equal to the page size and the data being of a size less than the page size; and
the error condition is internally correctable in the integrated circuit for a one bit error, and is externally correctable for at least a two bit error.

43. The method of claim 35 wherein the large codeword creating step comprises creating the single large codeword from sequential bits of the data with a bit-correcting ECC code.

44. An integrated circuit operable in an ECC memory write mode and an ECC memory read mode, comprising:
a data path disposed in the integrated circuit;
a data interface coupled to the data path for furnishing data thereto during the ECC write mode;
a flash memory array disposed in the integrated circuit and coupled to the data path; and
a bit-correcting sequential ECC correction engine disposed in the integrated circuit and coupled to the data path for:
sequentially receiving the data in bit-serial fashion and furnishing a write codeword derived from the data during the ECC write mode; and
sequentially receiving a read codeword, furnishing an error status indication based at least in part on an evaluation of a read syndrome derived from the read codeword during the ECC read mode, and correcting an error condition in the read codeword.

45. The integrated circuit of claim 44 wherein the ECC correction engine comprises:
a single syndrome generator coupled to the data path and configurable during the write mode for creating the write codeword from the first data, the write codeword being a single large codeword, and configurable during the read mode for generating the read syndrome from the read codeword; and
an error trapper coupled to the syndrome generator.

46. The integrated circuit of claim 45 wherein the single syndrome generator has a bit-serial coupling to the data path.

47. The integrated circuit of claim 45 wherein the syndrome generator uses a BCH ECC code.

48. The integrated circuit of claim 44 wherein the ECC correction engine comprises:
a single syndrome generator having a bit-serial coupling to the data path and configurable during the write mode for creating the write codeword from the first data, the write codeword being a single large codeword, and configurable during the read mode for generating the read syndrome from the read codeword;
an error trapper coupled to the syndrome generator;
a counter;
a sequencer coupled to the error trapper and the counter, and further coupled to the data path for furnishing an error status indicator;
address logic coupled to the counter; and
a bit inverter coupled to the address logic and to the data path.

49. The integrated circuit of claim 44 wherein the data interface comprises a bit-serial input/output circuit.

50. The integrated circuit of claim 44 further comprising a page memory disposed in the integrated circuit and coupled to the data path.

51. An integrated circuit comprising:
a data path disposed in the integrated circuit;
a bit-serial interface disposed in the integrated circuit and coupled to the data path;
a flash memory array disposed in the integrated circuit and coupled to the data path; and
a sequential correction engine having a bit-serial coupling to the data path, the correction engine using a bit-correcting ECC code to create a codeword and to generate a read syndrome from a codeword.

52. The integrated circuit of claim 51 wherein the correction engine uses a bit-correcting ECC code to create a single large write codeword and to generate a read syndrome from a single large read codeword.

53. The integrated circuit of claim 52 wherein:
the flash memory array is a page mode memory having a plurality of pages of a common page size; and
the write and read codewords are of a size equal or substantially equal to the page size.

54. A method of correcting erroneous data in an integrated circuit having a flash memory array, comprising:
receiving binary data in the integrated circuit;
sequentially processing bits of the data with a bit-correcting ECC code in the integrated circuit to create a codeword;
programming the codeword into the flash memory array;
reading the codeword from the flash memory array;
sequentially processing the codeword read in the reading step with the bit-correcting ECC code in the integrated circuit to generate a read syndrome;
evaluating the read syndrome to determine a condition of the codeword; and
when the codeword condition is an error condition, sequentially processing the codeword read in the reading step as determined by the read syndrome in an attempt to correct the error condition internally in the integrated circuit.

55. The method of claim 54 wherein the receiving step comprises receiving the binary data in the integrated circuit in a bit-serial manner.

56. The method of claim 54 further comprising successfully completing the step of sequentially processing the codeword read in the reading step as determined by the read syndrome when the error condition is a small error condition, whereby the error condition is corrected internally in the integrated circuit.

57. The method of claim 54 further comprising unsuccessfully completing the step of sequentially processing the codeword read in the reading step as determined by the read syndrome when the error condition is a large error condition.

58. A method of refreshing a flash memory array that is part of an integrated circuit, comprising:
reading an ECC codeword from a page of the flash memory array to a volatile memory having essentially a page of storage capacity, the volatile memory being part of the integrated circuit;
calculating a read syndrome from the ECC codeword, in the integrated circuit;
detecting an error condition in the ECC codeword and location information therefor from, at least in part, the read syndrome, in the integrated circuit;
correcting the error condition in the ECC codeword residing in the volatile memory by use of the location information, in the integrated circuit, to obtain a corrected ECC codeword having one or more corrected bit or bits; and
writing at least the corrected bit or bits of the corrected ECC codeword from the volatile memory to a page of the flash memory array.

59. The method of claim 58 further comprising:
obtaining data from the corrected ECC codeword residing in the volatile memory; and
furnishing the data to an application.

60. The method of claim 58 wherein the reading, calculating, detecting, correcting, and writing steps are performed as an internal background task.

61. The method of claim 58 wherein the reading, calculating, detecting, correcting, and writing steps are performed in response to a command from an application.

62. The method of claim 59 wherein the writing step is performed automatically after the correcting step.

63. The method of claim 59 further comprising:
reporting the error condition to the application; and
receiving a command from the application to refresh the flash memory array;
wherein the writing step is performed in response to the command in the receiving step.

64. The method of claim 58 wherein the writing step comprises writing the entire corrected ECC codeword.

65. A method of refreshing a flash memory array that is part of an integrated circuit, comprising:
reading an ECC codeword from a page of the flash memory array;
calculating a read syndrome from the ECC codeword, in the integrated circuit;
detecting an error condition in the ECC codeword and location information therefor from, at least in part, the read syndrome, in the integrated circuit;
correcting the error condition in the ECC codeword, in the integrated circuit, to obtain an ECC codeword having one or more corrected bit or bits; and
writing at least the corrected bit or bits of the ECC codeword to a page of the flash memory array.

66. The method of claim 65 wherein the reading, calculating, detecting, correcting, and writing steps are performed as an internal background task.

67. The method of claim 65 wherein the reading, calculating, detecting, correcting, and writing steps are performed in response to a command from an application.

68. The method of claim 65 wherein the writing step is performed automatically during memory read mode, after the correcting step.

69. The method of claim 65 further comprising:
reporting the error condition to the application; and
receiving a command from the application to refresh the flash memory array;
wherein the writing step is performed in response to the command in the receiving step.

70. A method of obtaining data from the flash memory array of an integrated circuit, comprising:
reading a plurality of ECC codewords from respective pages of the flash memory array in the integrated circuit, each of the ECC codewords comprising a data section and an ECC write syndrome section;
generating, in the integrated circuit, respective read syndromes from the ECC codewords, wherein some of the read syndromes indicate no erroneous data and others of the read syndromes indicate erroneous data;
attempting correction of the ECC codewords having respective read syndromes indicating erroneous data, in the integrated circuit;
for the ECC codewords successfully corrected in the correction attempting step, furnishing the data sections thereof as outputs from the integrated circuit;
for the ECC codewords unsuccessfully corrected in the correction attempting step, furnishing information suitable for off-chip recovery of data therefrom as outputs from the integrated circuit; and
for the ECC codewords having respective read syndromes indicating no erroneous data, furnishing the data sections thereof as outputs from the integrated circuit.

71. The method of claim 70 further comprising:
for the ECC codewords successfully corrected in the correction attempting step, reporting corrected error status prior to the step of furnishing the data sections thereof;
for the ECC codewords unsuccessfully corrected in the correction attempting step, reporting uncorrected error status prior to the step of furnishing the data sections thereof and the respective read syndromes; and
for the ECC codewords having respective read syndromes indicating no erroneous data, reporting no-error status prior to the step of furnishing the data sections thereof.

72. The method of claim 70 further comprising, for the ECC codewords successfully corrected in the correction attempting step, programming the corrected ECC codewords into respective pages of the flash memory array.

73. The method of claim 70 wherein the information furnished as the output of the integrated circuit for the ECC codewords unsuccessfully corrected in the correction attempting step comprises the ECC codewords unsuccessfully corrected in the correction attempting step.

74. The method of claim 70 wherein the information furnished as the output of the integrated circuit for the ECC codewords unsuccessfully corrected in the correction attempting step comprises the ECC codewords unsuccessfully corrected in the correction attempting step and the read syndromes generated therefrom.

75. The method of claim 70 wherein the information furnished as the output of the integrated circuit for the ECC codewords unsuccessfully corrected in the correction attempting step comprises data sections of the ECC codewords unsuccessfully corrected in the correction attempting step and the read syndromes generated therefrom.

76. A method of writing to the flash memory array of an integrated circuit, comprising:
serially receiving first data and a first command to write the first data without error correction;
programming a page of the flash memory array with the first data;
serially receiving second data and a second command to write the second data with error correction;
generating an ECC codeword from the second data; and
programming a page of the flash memory array with the ECC codeword.

77. The method of claim 76 wherein the generating step comprises:
generating an ECC write syndrome from the second data; and
combining the ECC write syndrome with the second data to form the ECC codeword.

78. A method of reading the flash memory array of an integrated circuit, comprising:
serially receiving a first command to read a first page of the flash memory array without error correction;
furnishing the first page of the flash memory array as serial output from the integrated circuit;
serially receiving a second command to read a second page of the flash memory array with error correction;
generating in the integrated circuit a read syndrome from an ECC codeword stored in the second page of the flash memory, the ECC codeword having a data section and a write syndrome section;
evaluating the read syndrome in the integrated circuit to detect an error condition in the ECC codeword;
correcting the error condition in the ECC codeword as determined by the read syndrome in the integrated circuit to obtain a corrected ECC codeword; and
furnishing the data section of the corrected first ECC codeword as output from the integrated circuit.

79. A method of correcting erroneous data in an integrated circuit having a flash memory array, comprising:
reading a codeword from the flash memory array, the codeword comprising data and a write syndrome;
generating a read syndrome in the integrated circuit from the codeword read in the reading step;
evaluating the read syndrome to determine whether an error condition exists in the codeword;
furnishing the data from the codeword as output from the integrated circuit based on the evaluating step, the data being uncorrected when the evaluating step indicates no error condition, the data being corrected based on the read syndrome when the evaluating step indicates an error condition and the error condition is correctable, and the data being uncorrected when the evaluating step indicates an error condition and the error condition is uncorrectable; and
prior to the data furnishing step, furnishing a data status as output from the integrated circuit, the data status being “error free” when the evaluating step indicates no error condition, the data status being “corrected error” when the evaluating step indicates an error condition and the error condition is correctable, and the data status being “uncorrectable error” when the evaluating step indicates an error condition and the error condition is uncorrectable.

80. A serial flash memory integrated circuit comprising:
a data path;
a flash memory array coupled to the data path;
a page memory coupled to the data path;
a bit-serial input/output interface coupled to the data path;
a sequential syndrome generator based on a bit-correcting ECC code having a bit-serial coupling to the data path and an output; and
an error trapper having an input coupled to the output of the syndrome generator.

81. A serial flash memory integrated circuit comprising:
a flash memory array;
a page memory coupled to the flash memory array;
a shift register coupled to the flash memory array and to the page memory;
a bit inverter coupled to the shift register;
a bit-serial input/output interface coupled to the shift register;
a sequential syndrome generator based on a bit-correcting ECC code and having a bit-serial coupling to the shift register and an output;
an error trapper having an input coupled to the output of the syndrome generator;
a zero detector coupled to the output of the syndrome generator;
a counter;
a sequencer coupled to the error trapper, the zero detector, and the counter, and having an error status output coupled to the input/output interface; and
address logic having an input coupled to the counter and an output coupled to the bit inverter.
